(19) United States
(12) Patent Application Publication
(10) Pub. No.: US 2004/0007169 A1
(43) Pub. Date: Jan. 15, 2004

(54) Semiconductor nanoparticles and thin film containing the same

(75) Inventors: Takeshi Ohtsu, Kanagawa (JP); Yasuko Saito, Kanagawa (JP); Manabu Kawa, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI CHEMICAL CORPORATION, Tokyo (JP)

(21) Appl. No.: 10/352,111

(22) Filed: Jan. 28, 2003

(30) Foreign Application Priority Data
Jan. 28, 2002 (JP) 2002-018546

(51) Int. Cl. C30B 23/00; C30B 25/00; C30B 28/12; C30B 28/14; C01B 33/26

(52) U.S. Cl. 117/84; 423/328.2

(57) ABSTRACT

Semiconductor nanoparticles, having a poly(alkylene glycol) residue attached to the surface of semiconductor crystals, exhibit hydrophilicity, a non-specific adsorbing property to biosubstances, and absorption and luminescence characteristics controlled by aquantum effect of the semiconductor crystals.

### BACKGROUND OF THE INVENTION

1. Field of the Invention

The present invention relates to semiconductor nanoparticles including semiconductor crystals and to thin film containing the same. More particularly, it relates to novel semiconductor nanoparticles having all of a controlled absorption or luminescence characteristic due to a quantum effect of the semiconductor crystals, good solubility in solvents and dispersity in polymers, and an excellent coating property and also relates to thin film containing the semiconductor nanoparticles. It also relates to a novel material which is applicable to various kinds of optical materials, biological analytical reagents, etc.

2. Discussion of the Background

In semiconductor nanoparticles such as semiconductor nanocrystals, quantized energy states can become separated and controlled as a function of particle size. Accordingly, in semiconductor nanoparticles, peak positions of the exciton absorption band can appear at a slightly lower energy than the absorption edge of fundamental absorption of the semiconductor crystals and can be controlled by changing the particle size of the semiconductor nanoparticles. Because the nanoparticles show electromagnetic wave absorption and luminescence abilities (hereinafter, referred to as absorption and luminescence abilities) different from bulk, semiconductor nanoparticles are expected to be used as luminescent materials and memory materials.

With regard to a method for the manufacture of semiconductor nanoparticles, there are exemplified conventional vacuum manufacturing processes such as a molecular beam epitaxy method (MBE method), a metallo-organic vapor-phase growth method (MOVPE method) and an atomic layer epitaxy method (ALE method). Although a highly pure product can be prepared by these vacuum manufacturing methods, the resulting nanoparticles are available only in a state of being strongly attached onto a substrate and they are unable to be freely utilized by dispersing them in a solvent or in a medium such as polymers.

With regard to the use where the characteristic of semiconductor nanoparticles is utilized, there are various uses including application to optical uses, such as a display panel, a light emitting diode, and a super resolution film for an optical disk and an optical waveguide, and also application to biological analytical reagents. For these applications, it is inevitable to develop semiconductor nanoparticles having a good dispersity in solvents and in polymers and an excellent coating property where absorption and luminescence abilities controlled by a quantum size effect are still maintained.

J. E. B. Katari, et al; J. Phys. Chem., volume 98, 4109-4117 (1994), for example, reports a synthetic method producing semiconductor crystal particles where an organic ligand expected to have good dispersity and solubility in polymers and in organic solvents is attached onto the surface of the particles. Semiconductor crystal particles synthesized by such a method have a structure where an organic ligand such as trioctylphosphine oxide (hereinafter, abbreviated as TOPO) is attached onto the surface of compound semiconductor crystal particles comprising cadmium selenide (CdSe) or the like. These particles have not only an excellent solubility in organic solvents such as toluene and methylene chloride but also a characteristic where a size distribution is very narrowly controlled. However, since it is believed that the semiconductor crystal particles prepared by such a method are coated with an alkyl group such an octyl group of TOPO having a small intermolecular cohesive force and are hydrophobic, these particles are not dispersed in an aqueous solvent such as alcohol and also hardly form thin film which inherently has both transparency and mechanical strength. In addition, their dispersity at high particle concentrations in commonly used amorphous resins having a practical resistance against thermal deformation such as acrylate resin represented by poly(methyl methacrylate) (usually called PMMA), styrene resin represented by polystyrene and aromatic polycarbonate resin represented by polystyrene results in a disadvantage of producting opaque high-molecular compositions.

D. V. Talapin, et al. reported in NANO LETTERS, volume 1, 207-211 (2001) that, when TOPO which is coordinated with CdSe is substituted with allylamine, peak luminescence intensity of the luminous band increases about 20-fold and the amino group may be a ligand which enhances the luminescence intensity. However, in alkylamines and alkenylamines, the surface of the particles is coated with an alkyl group or an alkenyl group such as TOPO and, therefore, there is a problem that solubility in aqueous solvents, dispersity in polymers and coating property are not sufficient.

On the other hand, in applying to biological analytical reagents where a biological interaction is utilized, it is usually necessary to give water solubility to the semiconductor nanoparticles. With regard to such a means, there is a report that, in A. L. Rogach, et al.: J. Phys. Chem. B, volume 103, page 3065 (1999) for example, cadmium selenide (CdSe) nanocrystals are synthesized from aqueous solution materials in the co-presence of various mercapto alcohols such as 2-mercaptoethanol and 1-thioglycerol and the mercapto alcohol is coordinated on the surface of the resulting CdSe nanocrystals. Accordingly, that method gives semiconductor nanoparticles having many hydroxyl groups on the surface. However, when an application to the above-mentioned analytical field is taken into consideration, hydroxyl groups function as proton donors in hydrogen bonds whereupon they are apt to cause indiscriminate adsorption of biosubstances due to non-specific interaction and there is concern regarding worsening the substrate-specific analytical precision.

In U.S. Pat. No. 5,990,479 (1999), there is disclosed a conception of semiconductor nanocrystal probes having a main object of biological applications where “affinity molecules” having affinity to specific substances (such as antibody, nucleic acid, protein, polysaccharide or low-molecular substances such as saccharide, peptide, pharmaceutical agent and ligand) are attached via “a linking agent” on the surface of semiconductor nanocrystals. In this patent specification, even synthesis of semiconductor nanoparticles where “a linking agent” having a reactive functional group which is able to attach “affinitive molecules” (such as carboxyl group, amino group, urea group —NHCONH₂, etc.) is fixed on the semiconductor nanocrystal surface is described as Examples. There is mentioned a conception that avidins such as avidin and streptavidin are able to be attached to such a functional group as “an affinitive molecule”. It is further mentioned that, when a specific affinity of avidins with biotin residues which has been widely used in biological analysis already is utilized, any substrate which is labeled with biotin residue is principally able to be analyzed. However, since all of the above-mentioned reactive functional groups function as a proton donor in hydrogen bonds, indiscriminate adsorption of biosubstances is apt to take place and there is concern regarding worsening the substrate-specific analytical precision. In addition, the attached amount of the avidins to the semiconductor nanoparticle surface which is a biological active point is not controlled and, therefore, that is not a satisfactory art in terms of analytical precision as analytical reagents.

In WO 00/17656, there is disclosed water-soluble semiconductor nanoparticles with an attached ligand of an alkanethiol having an ionic functional group, i.e. carboxylate group or sulfonate group, available at the terminus of the molecule. Although an excellent water solubility can be achieved by that art, there is still a problem of the non-specific interaction as same as above due to the ionic functional group and, further, there is a disadvantage that solubility of the semiconductor nanoparticles varies very greatly depending upon ionic strength (such as concentration of the co-existing salt) and hydrogen ion concentration of an aqueous solution.

The present invention has been achieved in view of the above-mentioned circumstances and its object is to provide semiconductor nanoparticles having a good dispersity in organic solvents and polymers, an excellent coating property and excellent absorption and luminescence characteristics.

### SUMMARY OF THE INVENTION

The present inventors have carried out intensive investigations for achieving the above-mentioned object and found that, when a poly(alkylene glycol) residue represented by polyethylene glycol is attached onto the surface of semiconductor crystals via, for example, a phosphorus-containing structure which will be mentioned later or an ω-aminofatty acid residue (where “ω-” is a common prefix in chemistry meaning that the substituent is terminally bonded), it is now possible to enhance the luminescence ability of the semiconductor crystals, to give good solubility and dispersity in organic solvents and polymers and to give an optically transparent thin film by dissolving the nanoparticles in an organic solvent followed by spin-coating, etc. whereupon the present invention has been achieved.

Thus, the first characteristic feature of the present invention is semiconductor nanoparticles where a poly(alkylene glycol) residue is attached onto the surface.

The second characteristic feature of the present invention is a thin film containing the above semiconductor nanoparticles.

### BRIEF DESCRIPTION OF THE DRAWINGS

FIG. 1 is a luminescence spectra of the CdS nanoparticles in toluene solution obtained in Synthetic Example 1 and Example 2.

FIG. 2 is a luminescence spectra of the CdSe nanoparticles in toluene solution obtained in Synthetic Example 2 and Example 3.

FIG. 3 is a luminescence spectra of the CdSe nanoparticles in toluene solution obtained in Synthetic Example 4 and Example 5.

FIG. 4 is a luminescence spectra of the CdS nanoparticles in toluene solution obtained in Synthetic Example 6 and Example 7.

FIG. 5 is a luminescence spectra of the InP/ZnS nanoparticles in chloroform solution obtained in Synthetic Example 11, Example 13 and Example 14.

### DETAILED DESCRIPTION OF PREFERRED EMBODIMENTS

Poly(alkylene glycol) Residue

The poly(alkylene glycol) residue in the present invention is a polymer represented by the following formula (3).

—(R³O)m—R⁴ (3)

In the formula (3), R³ is an alkylene group having 2-6 carbons; R⁴ is a structure which is freely selected from a group consisting of hydrogen atom, an alkyl group having 1-10 carbon(s), an aryl group having 10 or less carbons and an acyl group having 2-5 carbons; and m is a natural number of 50 or less.

Specific examples of R³ in the formula (3) are ethylene group, n-propylene group, isopropylene group, n-butylene group, isobutylene group, n-pentylene group, cyclopentylene group, n-hexylene group and cyclohexylene group. In view of solubility in aqueous solvents, preferably R³ is an alkylene group having 2-4 carbons such as ethylene group, n-propylene group, isopropylene group and n-butylene group. More preferably R³ is an alkylene group having 2 or 3 carbons such as ethylene group, n-propylene group and isopropylene group. Most preferably R³ is an ethylene group. In the formula (3), plural types of R³ may be present in a residue and, in that case, there is no limitation for the copolymerizing sequence thereof.

Specific examples of the alkyl group used for R⁴ in the formula (3) are methyl group, ethyl group, n-propyl group, isopropyl group, n-butyl group, isobutyl group, tert-butyl group, n-pentyl group, cyclopentyl group, n-hexyl group, cyclohexyl group, vinyl group, benzyl group and vinylbenzyl group. In view of solubility in aqueous solvents, preferably R⁴ is an alkyl group having 3 or less carbon(s) such as methyl group, ethyl group, n-propyl group and isopropyl group. More preferably R⁴ is a methyl group or ethyl group. Most preferably R⁴ is a methyl group. Specific examples of the aryl group used for the R⁴ are phenyl group, toluyl group (monomethylphenyl group), dimethylphenyl group, ethylphenyl group, isopropylphenyl group, 4-tert-butylphenyl group, vinylphenyl group, pyridyl group, monomethylpyridyl group and dimethylpyridyl group and, in view of solubility in aqueous solvents, phenyl group or pyridyl group is preferably used. Specific examples of the acyl group used for the above R⁴ are acetyl group, acryloyl group, methacryloyl group, crotonoyl group and maleoyl group and, in view of solubility in aqueous solvents, acetyl group is preferably used.

When a polymerizing group such as vinyl group, vinylbenzyl group, vinylphenyl group, acryloyl group, methacryloyl group, crotonoyl group and maleoyl group is used among the above-exemplified specific structures for the above R⁴, there are some cases where the semiconductor nanoparticles of the present invention acquire a copolymerizing property with, for example, radically polymerizing monomers or ionically polymerizing monomers.

The natural number (m) in the formula (3) is preferably 40 or less, more preferably 30 or less and, still more preferably, 20 or less and, in view of solubility, it is preferably 10 or less and, particularly preferably, 5 or less.

The particularly preferred structures of the formula (3) are a diethylene glycol residue (R³ is ethylene group and m=2) and a triethylene glycol residue (R³ is ethylene group and m=3), the more preferred ones are a diethylene glycol monoalkyl ether residue where R⁴ is methyl group or ethyl group where R⁴ is methyl group or ethyl group and a triethylene glycol monoalkyl ether residue and the most preferred ones are a diethylene glycol monomethyl ether residue and a triethylene glycol monomethyl ether residue (hereinafter, abbreviated as an MTEG residue) where R⁴ is methyl group.

In the present invention, such a poly(alkylene glycol) residue is attached as a ligand onto the surface of the semiconductor crystals which will be mentioned later by any bonding manner to give the semiconductor nanoparticles of the present invention. With regard to such a bonding manner, any bonding manner which is possible for the elements contained in the semiconductor crystals such as coordinate bond, covalent bond and ionic bond will be exemplified and specific examples are bonding manners where there are utilized a sulfur-containing structure such as mercapto group (another name: thiol group which is SH), sulfide bond (another name: thioether bond), disulfide bond (—S—S—) and thiourea group (NHCSNH₂), a group having a (P═O) structure such as phosphinic acid residue, phosphonic acid residue and phosphine oxide group, a nitrogen-containing structure such as nitrile group, amino group and pyridyl group, an acidic group such as carboxyl group and sulfonic acid group and a coordinating structure of amide group, etc. such as carboxylic acid amide group and sulfonic acid amide group. Preferred one among the above is a bond where any of a group having (P═O) structure, amino group and mercapto group is utilized.

The semiconductor nanoparticles of the present invention may contain a plurality of poly(alkylene glycol) residues.

Functional Group Having a (P═O) Structure

In the present invention, the above poly(alkylene glycol) residue is attached onto the surface of semiconductor crystals via an oxygen atom in a functional group having a (P═O) structure represented by the following formula (1) whereby, in addition to dispersity in solvents and resins, there is a significant improvement in absorption and luminescence efficiencies and, accordingly, that is particularly preferred.

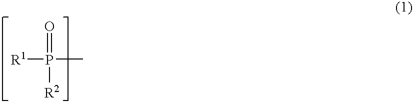

In the formula (1), P is bonded to R¹, R², O and the poly(alkylene glycol) residue. R¹ and R² each is any member selected from hydrogen atom, hydroxyl group, optionally substituted alkyl group, aryl group, alkoxy group and trialkylsilyl group having 8 or less carbon(s) and halogen atom and R¹ and R² may be same or different. Examples of the substituent in that case are halogen atom, nitro group, hydroxyl group and carboxyl group.

As a result of utilization of a functional group represented by the formula (1), luminescence ability of the semiconductor nanoparticles after coordination is significantly improved. It is likely to be due to a strong coordinating power of oxygen atom in the functional group represented by the formula (1) to transition metal element existing on the surface of the semiconductor crystals. Although the actual bonding structure of the said strong coordination powder is ambiguous, there is presumed the presence of coordination bond, etc. of oxygen.

When R¹ and R² each in the functional group represented by the formula (1) contains carbon atom, it is more preferred that its carbon numbers are not more than 5 so that no steric hindrance is resulted upon coordination to the semiconductor nanoparticles. Specific examples of R¹ and R² in the preferred functional group are hydrogen atom, hydroxyl group, an alkyl group such as methyl group, ethyl group and butyl group, an alkoxyl group such as methoxyl group, ethoxyl group and butoxyl group, a trialkylsilyl group such as trimethylsilyl group and halogen atom such as fluorine atom, chlorine atom and bromine atom. Among them, it is more preferred that at least one of R¹ and R² is hydroxyl group and it is most preferred that both R¹ and R² are hydroxyl groups in view of coordination power to the semiconductor crystals.

Linking Group for a poly(alkylene glycol) Residue with the Functional Group Represented by the Formula (1)

In the present invention, a linking group for the poly(alkylene glycol) residue with the functional group represented by the formula (1) may be freely selected. Its specific examples are an alkylene group, an alkenylene group and an alkynylene group or a compound where its carbon chain contains ether bond, ester bond, amide bond, carbonyl bond, amino group, thiocarbonyl group, etc. and a compound where one or more of hydrogen atoms thereof is/are substituted with halogen atom, nitro group, hydroxyl group, carboxyl group, an alkyl group having 4 or less carbon(s), an alkoxyl group having 4 or less carbon(s), an aryl group having 8 or less carbons, etc. Among them, an alkylene group and an alkenylene group are preferably used. Particularly, an alkylene group where the carbon chain comprises 6 or more carbons or, preferably, an alkylene group where the carbon chain comprises 6-20 carbons is most preferred since there are some cases where the effects of protecting the semiconductor crystals from outside and of stabilizing the absorption and luminescence characteristics are noted.

It is also possible that the poly(alkylene glycol) residue is directly bonded to the functional group represented by the formula (1).

To be more specific, the semiconductor nanoparticles where a compound represented by the following formula (10) is attached onto the semiconductor crystal surface are preferred because of an excellent luminescence characteristic and an excellent miscibility with the resin.

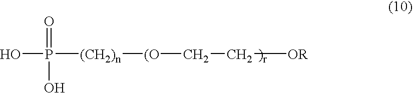

In the formula (10), R is hydrogen atom or an alkyl group having 7 or less carbon(s); n is a natural number of 20 or less; and r is from 2 to 10 and, preferably, 5 or less.

Specific examples of the compound represented by the formula (10) are 3,6,9-trioxaalkylphosphonic acid (2-(2-(2-alkoxyethoxy)ethoxy)ethylphosphonic acid) (n=2, r=2) and n-phosphonoalkyl triethylene glycol monomethyl ether (r=3).

n-Phosphonoalkyl triethylene glycol ethers

With regard to the molecular structure where a poly(alkylene glycol) residue and a functional group represented by the formula (1) are bonded which is preferably used as a ligand to the semiconductor crystals in the present invention, there may be exemplified n-phosphonoalkyl triethylene glycol ethers represented by the following formula (2).

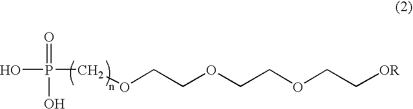

In the formula (2), R is hydrogen atom or an alkyl group having 7 or less carbon(s) and n is a natural number of 20 or less. Examples of the alkyl group used as R are as same as those in the case of R⁴ in the already-mentioned formula (3). In the formula (2), the lower limit of the natural number (n) is preferably 1 or more, more preferably 3 or more and, most preferably, 6 or more while the upper limit thereof is preferably 17 or less, more preferably 14 or less and, most preferably, 12 or less and, when value of the natural number (n) is 6 or more, there are some cases where the effects of protecting the semiconductor crystals from outside and of stabilizing its absorption and luminescence characteristics are noted. With regard to a particularly preferred specific compound, 10-phosphonodecyl MTEG ether (10-(2-(2-methoxyethoxy)ethoxy)ethoxdecylphosphonic acid) represented by the following formula (4) is exemplified.

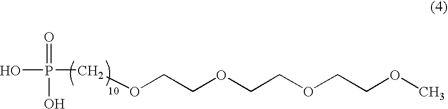

Functional Group Having an Amino Group

When such a poly(alkylene glycol) residue is attached onto the surface of the semiconductor crystals via an amino group or a functional group having an amino group in the present case, luminescence ability of the semiconductor nanoparticles after coordination is significantly improved. It is likely to be due to the fact that amino group has a strong coordinating power to transition metal element existing on the surface of the semiconductor crystals. Although the actual bonding structure of the amino group coordinating structure with the semiconductor crystal surface is ambiguous, the presence of coordination bond of nitrogen atom of the amino group or the like is presumed.

With regard to the functional group having an amino group, an ω-aminofatty acid residue is particularly preferred and that where a poly(alkylene glycol) residue is attached onto the semiconductor crystal surface via the said group is preferred in terms of luminescence characteristic and dispersity in solvents and resins. The ω-aminofatty acid residue used hereinabove is a structure represented by the following formula (5).

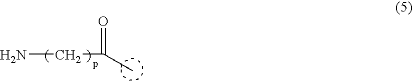

In the formula (5), p is a natural number of 20 or less and a circle with a broken line is a position to which the poly(alkylene glycol) residue is bonded.

Although there is no limitation for the bonding manner for the poly(alkylene glycol) residue with the ω-aminofatty acid residue, it is usually any of ester bond, amide bond and carbon-carbon single bond. Thus, in the case of an ester bond, it is a manner where a carbon atom in R³ at the left end in the formula (3) is bonded to a carbon atom in the carbonyl group in the formula (5) via, for example, one oxygen atom while, in the case of an amide bond, it is a manner where they are similarly bonded via one nitrogen atom. In such an amide bond, both primary amide and secondary amide are possible.

With regard to a molecular structure where a poly(alkylene glycol) residue and an ω-aminofatty acid residue are bonded which is preferably used as a ligand, there may be exemplified triethylene glycol esters of ω-aminofatty acid represented by the following formula (6).

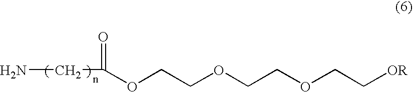

In the formula (6), R is hydrogen atom or an alkyl group having 7 or less carbon(s) and n is a natural number of 20 or less. Examples of the alkyl group used as R are the same as those in the case of R⁴ in the already-mentioned formula (3). The lower limit of the natural number n in the formula (1) is preferably 1 or more, more preferably 3 or more and, most preferably, 6 or more while the upper limit thereof is preferably 17 or less, more preferably 14 or less and, most preferably, 10 or less. When the value of the natural number n is 6 or more, there are some cases where there is noted an effect in which the semiconductor crystals are protected from outside whereby its absorption and luminescence characteristics are stabilized. With regard to the particularly preferred specific compound, 11-aminoundecanoic acid MTEG ester (2-(2-(2-methoxyethoxy)ethoxy)ethyl 11-aminoundecanoate) having the following formula (7) may be exemplified.

NH₂(CH₂)₁₀COO(CH₂CH₂O)₃CH₃ (7)

The esters of the above formula (6) are synthesized, for example, by a method where a condensing agent such as carbodiimide is added to ω-aminofatty acid such as 3-aminopropanoic acid or 11-aminoundecanoic acid and poly(alkylene glycol) which is in nearly equivalent thereto to esterify; a method where the said ω-aminofatty acid and an excessive amount of poly(alkylene glycol) are subjected to dehydrating esterification in the presence of an acid catalyst such as sulfuric acid or p-toluenesulfonic acid (if necessary, heating or dehydration in vacuo is carried out to accelerate the equilibrium reaction); a method where a lower alkyl ester such as methyl ester or ethyl ester of the said ω-aminofatty acid and an excessive amount of poly(alkylene glycol) are subjected to a transesterification in the presence of a strong acid such as sulfuric acid or p-toluenesulfonic acid or in the presence of a catalyst such as Lewis acid (if necessary, heating or vacuation is carried out to accelerate the equilibrium reaction); and a method where the said aminofatty acid is converted to an active species such as the corresponding acid chloride or acid hydride and then subjected to condensation reaction with poly(alkylene glycol) in the presence of a base. In that case, a protective group may be introduced into the amino group for preventing the reaction between the amino group and the carboxyl group.

Functional Group Having a Mercapto Group

In the present invention, a poly(alkylene glycol) residue is preferably attached onto the semiconductor crystal surface via a mercapto group or a functional group having a mercapto group. Among the above, that which is attached via an ω-mercaptofatty acid residue is particularly preferred. The ω-mercaptofatty acid residue referred to hereinabove is a structure represented by the following structure (8).

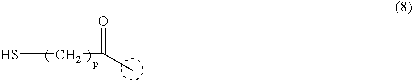

In the formula (8), p is a natural number of 20 or less and a circle with a broken line shows a position to which the poly(alkylene glycol) is bonded.

The semiconductor nanoparticles as such can be utilized as a biological analytical reagent which has an excellent water solubility and has a significantly reduced non-specific adsorption worsening the analytical precision as compared with the conventional ones when a chemical structure (such as antibody, nucleic acid and protein) having a biological interaction with a specific structure is further introduced thereinto.

Although there is no limitation for the bonding manner of the poly(alkylene glycol) residue with the ω-mercaptofatty acid residue, it is usually made in any of ester bond, amide bond and carbon-carbon single bond. Thus, in the case of an ester bond, it is a manner where a carbon atom at the left terminal R³ in the formula (3) and a carbon atom of carbonyl group in the formula (8) are bonded via, for example, one oxygen atom and, in the case of an amide bond, it is a manner where they are similarly bonded via one nitrogen atom. In such an amide bond, both primary amide and secondary amide are able to be used.

With regard to a molecular structure preferably used as a ligand where a poly(alkylene glycol) residue and an ω-mercaptofatty acid residue are bonded, there may be exemplified triethylene glycol esters of ω-mercaptofatty acid represented by the following formula (9).

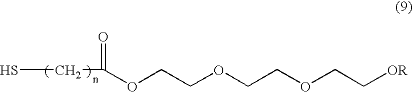

In the formula (9), R is hydrogen or an alkyl group having 7 or less carbon(s) and n is a natural number of 20 or less. Examples of the alkyl group used as R are the same as those in the case of R⁴ in the already-mentioned formula (3). The lower limit of the natural number n in the formula (9) is preferably 1 or more, more preferably 3 or more and, most preferably, 6 or more while the upper limit thereof is preferably 17 or less, more preferably 14 or less and, most preferably, 10 or less. When the value of the natural number n is 6 or more, there are some cases where an effect in which the semiconductor crystals are protected from outside whereby its absorption and luminescence characteristics are stabilized is noted. With regard to the particularly preferred specific compound, there are exemplified 11-mercaptoundecanoic acid MTEG esters (2-(2-(2-methoxyethoxy)ethoxy)ethyl 11-mercaptoundecanoate) having the following formula (10).

HS(CH₂)₁₀COO(CH₂CH₂O)₃CH₃ (10)

The esters of the above formula (10) are synthesized, for example, by a method where an ω-mercaptofatty acid such as 3-mercaptopropanoic acid or 11-mercaptoundecanoic acid and an excessive amount of poly(alkylene glycol) are subjected to a dehydrating esterification in the presence of an acid catalyst such as sulfuric acid or p-toluenesulfonic acid (if necessary, heating or dehydration in vacuo is carried out to accelerate the equilibrium reaction); a method where a lower alkyl ester such as methyl ester or ethyl ester of the said ω-mercaptofatty acid and an excessive amount of poly(alkylene glycol) are subjected to a transesterification in the presence of a strong acid such as sulfuric acid or p-toluenesulfonic acid or in the presence of a catalyst such as Lewis acid (if necessary, heating or vacuation is carried out to accelerate the equilibrium reaction); and a method where the said ω-mercaptofatty acid is converted to an active species such as the corresponding acid chloride or acid hydride and then subjected to a condensation reaction with poly(alkylene glycol) in the presence of a base.

Semiconductor Nanoparticles

In the semiconductor nanoparticles of the present invention, it mainly comprises the semiconductor crystals which will be mentioned later and the above-mentioned poly(alkylene glycol) residue is attached to the surface thereof. Accordingly, in the semiconductor nanoparticles of the present invention, the semiconductor crystals and the poly(alkylene glycol) residue attached to the surface thereof are essential constituent components.

It is preferred that the semiconductor crystals used in the present invention have exciton absorption and luminescence bands controlled by quantum effect in the absorption and luminescence spectra. The absorption and luminescence wavelengths which are particularly useful in practical use are light of from far-ultraviolet to infrared regions and its lower limit is within a region of usually 150 nm or more, preferably 180 nm or more, still more preferably 200 nm or more and, most preferably, 220 nm or more while the upper limit is within a region of usually 10,000 nm or less, preferably 8,000 nm or less, more preferably 6,000 nm or less and, most preferably, 4,000 nm or less. The above-mentioned exciton absorption and luminescence bands are phenomenalistically dependent upon the particle size of the said semiconductor crystals.

The semiconductor crystals may be any of semiconductor single crystal, mixed crystals where plural semiconductor crystal compositions are phase-separated and mixed semiconductor crystals where phase separation is not observed and also may be in a core-shell structure which will be mentioned later.

Particle size of such semiconductor crystals is usually from 0.5 nm or more to 20 nm or less in terms of a number-average particle size and, in view of controlling property of the absorption and luminescence wavelengths by quantum effect, the lower limit is preferably 1 nm or more, more preferably 2 nm or more and, most preferably, 3 nm or more while the upper limit is preferably 15 nm or less, more preferably 12 nm or less and, most preferably, 10 mn or less. For determining the said number-average particle size, the value measured from the image of the given semiconductor nanoparticles observed under a transmission electron microscope (TEM) is used. Thus, diameter of a circle having the same area with the particle image of the observed semiconductor crystals is defined as the particle size of the particle image. The particle size determined as such is used and the number-average particle size is calculated by, for example, means of a known statistically processing means for image data. It is of course preferred that the numbers of the particle images (numbers of the statistically processed data) of the semiconductor crystals used in such a statistical process are as many as possible and, in the present invention, the number of particle images randomly selected are at least 50 or more, preferably 80 or more and, more preferably, 100 or more in view of the reproducibility.

When the number-average particle size is too big, there are some cases where an aggregating property increases to a large extent or a controlling property of exciton absorption and luminescence by quantum effect decreases while, when it is too small, there some cases where a crystal function of the semiconductor crystal particle (such as formation of a band structure giving luminescence power) decreases or the isolation yield upon manufacture decreases to a large extent and none of these is preferred. Incidentally, when the atomic number of the element contained in the semiconductor crystals is too small whereby contrast by electron beam in an observation under a TEM is hardly available, it is possible to estimate the particle size by an observation under an atomic force microscope (AFM) or by a combination of a composition analysis result such as elementary analysis with measurement of neutron scattering or light scattering in a solution.

Although there is no limitation for the particle size distribution of the semiconductor crystals, it is possible to change the wavelength width of absorption and luminescence bands by changing such a distribution in case an exciton absorption and luminescence bands of the semiconductor crystals are utilized. When it is necessary to make the wavelength width narrow, the particle size distribution is made narrow and, usually, the standard deviation is made within ±40%, preferably within ±30%, more preferably within ±20% and, most preferably, within ±10%. In the case where the particle size distribution is more than the range of standard deviation, it is difficult to fully achieve an object of making the wavelength width of exciton absorption and luminescence bands narrow.

Composition of Semiconductor Crystals

When the composition example of the above-mentioned semiconductor crystals is expressed by a composition formula, the following may be exemplified: they are a single substance of element of group 14 of the periodic table such as C, Si, Ge and Sn; a single substance of element of group 15 of the periodic table such as P (black phosphorus); a single substance of element of group 16 of the periodic table such as Se and Te; a compound comprising plural elements of group 14 of the periodic table such as SiC; a compound of element of group 14 of the periodic table with element of group 16 of the periodic table such as SnO₂, Sn(II)Sn(IV)S₃, SnS₂, SnS, SnSe, SnTe, PbS, PbSe and PbTe; a compound of element of group 13 of the periodic table with element of group 15 of the periodic table (or semiconductor of a compound of group III-group V) such as BN, BP, BAs, AlN, AlP, AlAs, AlSb, GaN, GaP, GaAs, GaSb, InN, Inp, InAs and InSb; a compound of element of group 13 of the periodic table with element of group 16 of the periodic table such as Al₂S₃, Al₂Se₃, Ga₂S₃, Ga₂Se₃, Ga₂Te₃, In₂O₃, In₂S₃, In₂Se₃ and In₂Te₃; a compound of element group 13 of the periodic table with element of group 17 of the periodic table such as TlCl, TlBr and TlI; a compound of element of group 12 of the periodic table with element of group 16 of the periodic table (or semiconductor of a compound of group II-group VI) such as ZnO, ZnS, ZnSe, ZnTe, CdO, CdS, CdSe, CdTe, HgS, HgSe and HgTe; a compound of element of group 15 of the periodic table with element of group 16 of the periodic table such as As₂S₃, As₂Se₃, As₂Te₃, Sb₂S₃, Sb₂Se₃, Sb₂Te₃, Bi₂S₃, Bi₂Se₃ and Bi₂Te₃; a compound of element of group 11 of the periodic table with element of group 16 of the periodic table such as Cu₂O and Cu₂Se; a compound of element of group 11 of the periodic table with element of group 17 of the periodic table such as CuCl, CuBr, CuI, AgCl and AgBr; a compound of element of group 10 of the periodic table with element of group 16 of the periodic table such as NiO; a compound of element of group 9 of the periodic table with element of group 16 of the periodic table such as CoO and CoS; a compound of element of group 8 of the periodic table with element of group 16 of the periodic table such as iron oxide (e.g., Fe₃O₄) and FeS; a compound of element of group 7 of the periodic table with element of group 16 of the periodic table such as MnO; a compound of element of group 6 of the periodic table with element of group 16 of the periodic table such as MoS₂ and WO₂; a compound of element of group 5 of the periodic table with element of group 16 of the periodic table such as VO, VO₂ and Ta₂O₅; a compound of element of group 4 of the periodic table with element of group 16 of the periodic table such as titanium oxide (e.g., TiO₂, Ti₂O₅, Ti₂O₃ and Ti₅O₉; where the crystal type may be any of a rutile type, a mixed type of rutile/anatase and an anatase type) and ZrO₂; a compound of element of group 2 of the periodic table with element of group 16 of the periodic table such as MgS and MgSe; a chalcogen spinel such as CdCr₂O₄, CdCr₂Se₄, CuCr₂S₄ and HgCr₂Se₄; and BaTiO₃. Similarly are exemplified semiconductor clusters where their structures are established such as (BN)₇₅(BF₂)₁₅F₁₅ reported by G. Schmid, et al. in Adv. Mater., volume 4, page 494 (1991) and Cu₁₄₆Se₇₃(triethylphosphine)₂₂ reported by D. Fenske, et al. in Angew. Chem. Int. Ed. Engl., volume 29, page 1452 (1990).

Among them, examples of the practically important ones are a single substance of group 14 such as Si and Ge; a compound of element of group 14 of the periodic table with element of group 16 of the periodic table such as SnO₂, SnS₂, SnS, SnSe, SnTe, Pbs, PbSe and PbTe; a group III-group V compound semiconductor such as GaN, GaP, GaAs, GaSb, InN, InP, InAs and InSb; a compound of element of group 13 of the periodic table with element of group 16 of the periodic table such as Ga₂O₃, Ga₂S₃, Ga₂Se₃, Ga₂Te₃, In₂O₃, In₂S₃, In₂Se₃ and In₂Te₃; a group II-group VI compound semiconductor such as ZnO, ZnS, ZnSe, ZnTe, CdO, CdS, CdSe, CdTe, HgO, HgS, HgSe and HgTe; a compound of element of group 15 of the periodic table with element of group 16 of the periodic table such as As₂O₃, As₂S₃, As₂Se₃, As₂Te₃, Sb₂O₃, Sb₂S₃, Sb₂Se₃, Sb₂Te₃, Bi₂O₃, Bi₂S₃, Bi₂Se₃ and Bi₂Te₃; a compound of element of group 8 of the periodic table with element of group 16 of the periodic table such as iron oxide (e.g., Fe₃O₄) and FeS; a compound of element of group 4 of the periodic table with element of group 16 of the periodic table such as the above-mentioned titanium oxide and ZrO₂; and a compound of element of group 2 of the periodic table with element of group 16 of the periodic table such as MgS and MgSe.

Among the above, Si, Ge, SnO₂, GaN, GaP, In₂O₃, InN, InP, Ga₂O₃, Ga₂S₃, In₂O₃, In₂S₃, ZnO, ZnS, CdO, CdS, the above-mentioned titanium oxides, ZrO₂, MgS, etc. have a characteristic of having a high refractive index and, in addition, they do not contain a highly toxic negative element whereby they are preferred in view of prevention of environmental pollution and safety to living organisms. From such a viewpoint, the compositions containing no highly toxic positive elements such as SnO₂, In₂O₃, ZnO, ZnS, the above-mentioned titanium oxide and ZrO₂ are more preferred and, among them, metal oxide semiconductor crystals such as ZnO or the above-mentioned titanium oxide (in view of an object of high refractive index, crystals of a rutile type is particularly preferred) and ZrO₂ are most preferred. Incidentally, absorption edge at the long wavelength side of titanium oxide crystal particles of a rutile type is usually near 400 nm in its bulk state and, when number-average particle size of the crystal particles is made within the above-mentioned range, it is possible to shift the absorption edge wavelength at the long wavelength side to shorter wavelength and there are some cases where an advantage that colorless property in a visible region is improved can be resulted. Further, colored semiconductor crystals having absorption property in visible region such as iron oxides and cobalt blue (a compounded oxide of Co and Al) are important for the use as color materials such as pigments.

Important ones are those having luminescence bands at and near the practically important visible region are group III-group V compound semiconductors such as GaN, GaP, GaAs, InN and InP; group II-group VI compound semiconductors such as ZnO, ZnS, ZnSe, ZnTe, CdO, CdS, CdSe, CdTe, HgO and HgS; Si; Ge; In₂O₃; In₂S₃ and the like. Among the above, preferred ones in view of a controlling property for crystal particle size and a luminescence property are group III-group V compound semiconductors such as GaN, GaP, GaAs, InN and InP and group II-group VI compound semiconductors such as ZnO, ZnS, ZnSe, ZnTe, CdO, CdS and CdSe. Particularly, ZnSe, CdS, CdSe, InP, etc. are more advantageously used for such an object.

If necessary, element such as Al, Mn, Cu, Zn, Ag, Cl, Ce, Eu, Tb or Er may be added to any of the above-exemplified semiconductor crystal compositions as a minor dopant substance (which means impurities are added intentionally).

Semiconductor Crystals of a Core-Shell Type

As reported by A. R. Kortan, et al.: J. Am. Chem. Soc., volume 112, page 1327 (1990) or in the specification of U.S. Pat. No. 5,985,173 (1999) for example, when the above-mentioned semiconductor crystals are made into the so-called core-shell structure comprising core and shell with an object of improving the electron excitation characteristic of the semiconductor crystals, there are some cases where the stability of quantum effect of the semiconductor crystals constituting the core is improved whereby there are some cases in which that is advantageous for a use where exciton absorption and luminescence bands are utilized. In that case, it is generally effective that, as a composition for the semiconductor crystals of the shell, the composition having more forbidden band gap than the core is used so as to form an energy barrier. This is presumed to be due to the construction which suppresses the influence from outside and also the influence such as that by undesired surface level caused by crystal lattice defect on the crystal surface.

With regard to the composition of the semiconductor crystals which is advantageously used for such a shell, although that is dependent upon the band gap of the core semiconductor crystals, that where the band gap in a bulk state is 2.0 electron volts or more at the temperature of 300° K is advantageous used and its examples are group III-group V compound semiconductors such as BN, BAs, GaN and GaP, group II-group VI compound semiconductors such as ZnO, ZnS, ZnSe, ZnTe, CdO and CdS and compounds of element of group 2 in the periodic table with element of group 16 of the periodic table such as MgS and MgSe. Among those, the semiconductor composition giving more preferred shell is that where the band gap in a bulk state is 2.3 electron volts (eV) or more at the temperature of 300° K and its examples are group III-group V compound semiconductors such as BN, BAS and GaN, group II-group VI compound semiconductors such as ZnO, ZnS, ZnSe and CdS and compounds of element of group 2 of the periodic table with element of group 16 of the periodic table such as MgS and MgSe. The most preferred one is that where the band gap in a bulk state is 2.5 electron volts (eV) or more at the temperature of 300° K and its examples are BN, BAS, GaN, ZnO, ZnS, ZnSe, MgS and MgSe. In view of chemical synthesis, ZnS is used most advantageously.

When examples of combination of the core-shell composition which is particularly advantageous upon use as the semiconductor crystals in the present invention are expressed by the composition formulae, they are CdSe—ZnS, CdSe—ZnO, CdSe—CdS, CdS—ZnS, CdS—ZnO, ZnSe—ZnS, InP—ZnS, etc.

Auxiliary Ligand

The semiconductor crystal nanoparticles of the present invention may have other auxiliary ligands than the above-mentioned poly(alkylene glycol) residue on their surface with an object of suppressing the undesired action such as aggregation resulting in stabilization. Such ligands will be exemplified hereunder.

(a) Sulfur-containing compounds: Mercaptoalkanes such as mercaptoethane, 1-mercapto-n-propane, 1-mercapto-n-butane, 1-mercapto-n-hexane, mercaptocyclohexane, 1-mercapto-n-octane and 1-mercapto-n-decane; thiophenol and thiophenol derivatives such as 4-methylthiophenol, 4-tert-butylthiophenol and 4-hydroxythiophenol; dialkyl sulfoxides such as dimethyl sulfoxide, diethyl sulfoxide, dibutyl sulfoxide, dihexyl sulfoxide, dioctyl sulfoxide and dodecyl sulfoxide; dialkyl disulfides such as dimethyl disulfide, diethyl disulfide, dibutyl disulfide, dihexyl disulfide, dioctyl disulfide and dodecyl disulfide; compounds having thiocarbonyl group such as thiourea and thioacetamide; sulfur-containing aromatic compounds such as thiophene; etc.

(b) Phosphorus-containing compounds: Trialkylphosphines such as triethylphosphine, tributylphosphine, trihexylphosphine, trioctylphosphine, tridecylphosphine and tris(3-hydroxypropyl)phosphine; trialkylphosphine oxides such as triethylphosphine oxide, tributylphosphine oxide, trihexylphosphine oxide, trioctylphosphine oxide (abbreviation: TOPO), tridecylphosphine oxide and tris(3-hydroxyprophyl)phosphine oxide; aromatic phosphines such as triphenylphosphine; aromatic phosphine oxides such as triphenylphosphine oxide; etc.

(c) Nitrogen-containing compounds: Nitrogen-containing aromatic compounds such as pyridine and quinoline; secondary amines such as diethylamine, dibutylamine, dihexylamine, dioctylamine, dodecylamine, diphenylamine, dibenzylamine and diethanolamine; primary amines such as hexylamine, octylamine, decylamine, dodecylamine, hexadecylamine, octadecylamine, phenylamine, benzylamine and 2-aminoethanol; carboxylates having amino group such as triethyl nitrilotriacetate; etc.

Among the auxiliary ligands exemplified hereinabove, preferred ones are the sulfur-containing compounds such as mercaptoalkanes having 6 or less carbons (e.g., mercaptoethane, 1-mercapto-n-propane, 1-mercapto-n-butane, 1-mercapto-n-hexane and mercaptocyclohexane), thiophenol and thiophenol derivatives (e.g., 4-methylthiophenol and 4-tert-butylthiophenol) and dialkyl sulfoxides having 8 or less total carbons (e.g., dimethyl sulfoxide, diethyl sulfoxide and dibutyl sulfoxide); the phosphorus-containing compounds such as trialkylphosphines (e.g., tributylphosphine, trihexylphosphine and trioctylphosphine) and trialkylphosphine oxides having 24 or less total carbons (e.g., triethylphosphine oxide, tributylphosphine oxide, trihexylphosphine oxide and trioctylphosphine oxide); and the primary amines (e.g., hexadecylamine). Among the above, the more preferred ones are the sulfur-containing compounds such as mercaptoalkanes having 4 or less carbons (e.g., mercaptoethane and 1-mercapto-n-butane) and thiophenol and its derivatives (e.g., 4-methylthiophenol and 4-tert-butylthiophenol); and the phosphorus-containing compounds such as trialkylphosphines having 18 or less total carbons (e.g., tributylphosphine and trihexylphosphine) and trialkylphosphine oxides having 18 or less total carbons (e.g., tributyl phosphine oxide and trihexylphosphine oxide).

Method for the Manufacture of the Semiconductor Crystals

Any method including the following conventionally conducted methods for the manufacture of semiconductor crystals may be used. Although the above-mentioned vacuum manufacturing process may be utilized, the following three liquid-phase methods may be exemplified as appropriate ones.

(a) A method where an aqueous solution of materials is made to exist as reversed micelle in a nonpolar organic solvent and crystal growth is carried out in the reversed micelle phase (hereinafter, referred to as “reversed micelle method”). This is a method reported, for example, in B. S. Zou, et al.: Int. J. Quant. Chem., volume 72, 439 (1999). This is a method suitable for an industrial production because of the reasons that the known reversed micelle stabilizing technique can be utilized in commonly-used reactors, that salts which are relatively less expensive and chemically stable can be used as the materials and further that the process is carried out at relatively low temperature which is not higher than the boiling point of water. However, as compared with the following hot soap method, there are some cases where luminescence characteristic is poor under the current state of technique.

(b) A method where thermodegradable materials are injected into a liquid-phase organic medium of high temperature whereby crystal growth is carried out (hereinafter, referred to as a hot soap method). This is a method reported, for example, in the already-mentioned literature by Katari, et al. As compared with the above reversed micelle method, it is now possible to give semiconductor crystal particles having excellent particle size distribution and purity and there is a characteristic that the product has an excellent luminescence characteristic and is usually soluble in organic solvents. With an object of desirable control of the reaction rate during the process of crystal growth in the liquid phase in the hot soap method, coordination organic compounds having an appropriate coordination power to the semiconductor-constituting elements are selected as liquid-phase components (acting as both solvent and ligand). Examples of such coordination organic compounds are the above-mentioned trialkylphosphines, the above-mentioned trialkylphosphine oxides, ω-aminoalkanes such as dodecylamine, tetradecylamine, hexadecylamine and octadecylamine and the above-mentioned dialkyl sulfoxides. Among those, preferred ones are the above-mentioned trialkylphosphine oxides such as TOPO, the ω-aminoalkanes such as hexadecylamine, etc.

(c) There has been already known a method which is a reaction solution where growth of semiconductor crystals similar to the above hot soap method takes place although an acid-base reaction is used as a driving force and the process is carried out at relatively low temperature (e.g., P. A. Jackson: J. Cryst. Growth, volumes 3-4, page 395 (1968)). Such a method may be sometimes classified under the name of a sol-gel method.

With regard to the semiconductor material substances which can be used for the above-mentioned three liquid-phase manufacturing methods, there are listed substances containing the positive elements selected from groups 2-15 of the periodic table and substances containing the negative elements selected from groups 15-17 of the periodic table. For example, in the above hot soap method, there is advantageously used a method where organic metal such as dimethyl cadmium or diethyl zinc is made to react in TOPO with a solution of a single substance of selenium in tertiary phosphine such as trioctylphosphine or tributylphosphine or with a chalcogenide element compound such as bis(trimethylsilyl) sulfide. When zinc oxide, for example, is manufactured in the above-mentioned solution reaction (c), there is advantageously used a method mentioned in L. Spanhel, et al.: J. Am. Chem. Soc., volume 113, page 2826 (1991) where zinc acetate is made to react with lithium hydroxide in ethanol. When there is a plurality of semiconductor material substances, they may be previously mixed or each of them may be injected into the reaction liquid phase. Those materials may be used as a solution using an appropriate diluting solvent.

Examples of the compound containing positive element used as the material compound for semiconductors are dialkylated compounds of element of group 2 of the periodic table such as diethyl magnesium and di-n-butyl magnesium; alkyl halides of element of group 2 of the periodic table such as methyl magnesium chloride, methyl magnesium bromide, methyl magnesium iodide and ethynyl magnesium chloride; dihalides of element of group 2 of the periodic table such as magnesium iodide; halides of element of group 4 of the periodic table such as titanium (IV) tetrachloride, titanium (IV) tetrabromide and titanium (IV) tetraiodide; halides of element of group 5 of the periodic table such as vanadium (II) dichloride, vanadium (IV) tetrachloride, vanadium (II) dibromide, vanadium (IV) tetrabromide, vanadium (II) diiodide, vanadium (IV) tetraiodide, tantalum (V) pentachloride, tantalum (V) pentabromide and tantalum (V) pentaiodide; halides of element of group 6 of the periodic table such as chromium (III) tribromide, chromium (III) triiodide, molybdenum (IV) tetrachloride, molybdenum (IV) tetrabromide, molybdenum (IV) tetraiodide, tungsten (IV) tetrachloride and tungsten (IV) tetrabromide; halides of element of group 7 of the periodic table such as manganese (II) dichloride, manganese (II) dibromide and manganese (II) diiodide; halides of element of group 8 of the periodic table such as iron (II) dichloride, iron (III) trichloride, iron (II) dibromide, iron (III) tribromide, iron (II) diiodide and iron (III) triiodide; halides of element of group 9 of the periodic table such as cobalt (II) dichloride, cobalt (II) dibromide and cobalt (II) diiodide; halides of element of group 10 of the periodic table such as nickel (II) dichloride, nickel (II) dibromide and nickel (II) diiodide; halides of element of group 11 of the periodic table such as copper (I) iodide; dialkylated compounds of element of group 12 of the periodic table such as dimethyl zinc, diethyl zinc, di-n-propyl zinc, diisopropyl zinc, di-n-butyl zinc, diisobutyl zinc, di-n-hexyl zinc, dicyclohexyl zinc, dimethyl cadmium, diethyl cadmium, dimethyl mercury (II), diethyl mercury (II) and dibenzyl mercury (II); alkyl halides of element of group 12 of the periodic table such as methyl zinc chloride, methyl zinc bromide, methyl zinc iodide, ethyl zinc iodide, methyl cadmium chloride and methyl mercury (II) chloride; dihalides of element of group 12 of the periodic table such as zinc dichloride, zinc dibromide, zinc diiodide, cadmium dichloride, cadmium dibromide, cadmium diiodide, mercury (II) dichloride, zinc chloride iodide, cadmium chloride iodide, mercury (II) chloride iodide, zinc bromide iodide, cadmium bromide iodide and mercury (II) bromide iodide; carboxylates of element of group 12 of the periodic table such as zinc acetate, cadmium acetate and cadmium 2-ethylhexanoate; oxides of element of group 12 of the periodic table such as cadmium oxide and zinc oxide; trialkylated compounds of element of group 13 of the periodic table such as trimethyl boron, tri-n-propyl boron, triisopropyl boron, trimethyl aluminum, triethyl aluminum, tri-n-butyl aluminum, tri-n-hexyl aluminum, trioctyl aluminum, tri-n-butyl gallium (III), trimethyl indium (III), triethyl indium (III) and tri-n-butyl indium (III); dialkyl monohalides of element of group 13 of the periodic table such as dimethyl aluminum chloride, diethyl aluminum chloride, di-n-butyl aluminum chloride, diethyl aluminum bromide, diethyl aluminum iodide, di-n-butyl gallium (III) chloride and di-n-butyl indium (III) chloride; monoalkyl dihalides of element of group 13 of the periodic table such as methyl aluminum dichloride, ethyl aluminum dichloride, ethyl aluminum dibromide, ethyl aluminum diiodide, n-butyl aluminum dichloride, n-butyl gallium (III) dichloride and n-butyl indium (III) dichloride; trihalides of element of group 13 of the periodic table such as boron trichloride, boron tribromide, boron triiodide, aluminum trichloride, aluminum tribromide, aluminum triiodide, gallium (III) trichloride, gallium (III) tribromide, gallium (III) triiodide, indium (III) trichloride, indium (III) tribromide, indium (III) triiodide, gallium (III) dichloride bromide, gallium (III) dichloride iodide, gallium (III) chloride diiodide and indium (III) dichloride iodide; carboxylates of element of group 13 of the periodic table such as indium (III) acetate and gallium (III) acetate; halides of element of group 14 of the periodic table such as germanium (IV) tetrachloride, germanium (IV) tetrabromide, germanium (IV) tetraiodide, tin (II) dichloride, tin (IV) tetrachloride, tin (II) dibromide, tin (IV) tetrabromide, tin (II) diiodide, tin (IV) tetrabromide, tin (IV) dichloride diiodide, tin (IV) tetraiodide, lead (II) dichloride, lead (II) dibromide and lead (II) diiodide; hydrides and alkylated products of element of group 14 of the periodic table such as such as diphenylsilane; trialkylated products of element of group 15 of the periodic table such as trimethyl antimony (III), triethyl antimony (III), tri-n-butyl antimony (III), trimethyl bismuth (III), triethyl bismuth (III) and tri-n-butyl bismuth (III); monoalkyl dihalides of element of group 15 of the periodic table such as such as methyl antimony (III) dichloride, methyl antimony (III) dibromide, methyl antimony (III) diiodide, ethyl antimony (III) diiodide, methyl bismuth (III) dichloride and ethyl bismuth (III) diiodide; trihalides of element of group 15 of the periodic table such as such as arsenic (III) trichloride, arsenic (III) tribromide, arsenic (III) triiodide, antimony (III) trichloride, antimony (III) tribromide, antimony (III) triiodide, bismuth (III) trichioride, bismuth (III) tribromide and bismuth (III) triiodide; etc.

Incidentally, halides of element of group 14 of the periodic table such as germanium (IV) tetrachloride, germanium (IV) tetrabromide, germanium (IV) tetraiodide, tin (II) dichloride, tin (IV) tetrachloride, tin (II) dibromide, tin (IV) tetrabromide, tin (II) diiodide, tin (IV) tetrabromide, tin (IV) dichloride diiodide, tin (IV) tetraiodide, lead (II) dichloride, lead (II) dibromide and lead (II) diiodide and hydrides and alkylated products of element of group 14 of the periodic table such as diphenylsilane may be solely used as a material for nanoparticles of single substance semiconductors of element of group 14 of the periodic table such as Si, Ge and Sn.

Examples of a compound containing the negative element to be used as a material compound for semiconductors are a single substance of element of groups 15-17 of the periodic table such as nitrogen, phosphorus, arsenic, antimony, bismuth, oxygen, sulfur, selenium, tellurium, fluorine, chlorine, bromine and iodine; hydrides of element of group 15 of the periodic table such as ammonia, phosphine (PH₃), arsine (AsH₃) and stibine (SbH₃); silylated compounds of element of group 15 of the periodic table such as tris(trimethylsilyl)amine, tris(trimethylsilyl)phosphine and tris(trimehtylsilyl)arsine; silylated compounds of element of group 16 of the periodic table such as hydrogen arsenide, hydrogen selenide and hydrogen telluride; silylated compounds of element of group 16 of the periodic table such as bis(trimethylsilyl) sulfide and bis(trimethylsilyl) selenide; alkaline metal salts of element of group 16 of the periodic table such as sodium sulfide and sodium selenide; trialkylphosphine chalcogenides such as tributylphosphine sulfide, trihexylphosphine sulfide, trioctylphosphine sulfide, tributylphosphine selenide, trihexylphosphine selenide and trioctylphosphine selenide; hydrides of element of group 17 of the periodic table such as hydrogen fluoride, hydrogen chloride, hydrogen bromide and hydrogen iodide; and silylated products of element of group 17 of the periodic table such as trimethylsilyl chloride, trimethylsilyl bromide and trimethylsilyl iodide. Among them, in view of reactivity and stability as well as operability of the compound, preferably used ones are a single substance of element of groups 15-17 of the periodic table such as phosphorus, arsenic, antimony, bismuth, sulfur, selenium, tellurium and iodine; silylated products of element of group 15 of the periodic table such as tris(trimethylsilyl) phosphine and tris(trimethylsilyl) arsine; hydrides of element of group 16 of the periodic table such as hydrogen sulfide, hydrogen selenide and hydrogen telluride; silylated products of element of group 16 of the periodic table such as such as bis(trimethylsilyl) sulfide and bis(trimethylsilyl) selenide; alkaline metal salts of element of group 16 of the periodic table such as sodium sulfide and sodium selenide; trialkylphosphine chalcogenides such as tributylphosphine sulfide, trihexylphosphine sulfide, trioctylphosphine sulfide, tributylphosphine selenide, trihexylphosphine selenide and trioctylphosphine selenide; silylated products of element of group 17 of the periodic table such as trimethylsilyl chloride, trimethylsilyl bromide and trimethylsilyl iodide; etc. Among the above, the particularly preferably used ones are a single substance of element of groups 15 and 16 of the periodic table such as phosphorus, arsenic, antimony, sulfur and selenium; silylated products of element of group 15 of the periodic table such as tris(trimethylsilyl) phosphine and tris(trimethylsilyl) arsine; silylated products of element of group 16 of the periodic table such as bis(trimethylsilyl) sulfide and bis(trimethylsilyl) selenide; alkaline metal salts of element of group 16 of the periodic table such as such as sodium sulfide and sodium selenide; trialkylphosphine chalcogenides such as tributylphosphine sulfide, trioctylphosphine sulfide, tributylphosphine selenide and trioctylphosphine selenide; etc.

Although there is no limitation for the supplying rate of the above-mentioned material compound to the reaction liquid phase in a hot soap method which is a particularly preferred liquid-phase manufacturing method, it is sometimes advantageous to inject the predetermined amount within a period of as short as 0.1-60 second(s) when the particle size distribution of the resulting semiconductor crystal nanoparticles is made narrow. Further, although an appropriate crystal growth reaction time (retention time in the case of a flow method) after injection of the material solution varies depending upon the semiconductor species, desired particle size or reaction temperature, the representative condition is about from 1 minute to 10 hours at the reaction temperature of about 200-350° C.

In such a hot soap method, isolation and purification are usually carried out after completion of the growth reaction of the semiconductor crystals. With regard to a method therefor, concentration of the liquid phase components or a precipitation method is appropriate. Preferred and representative procedure for the precipitation method is as follows. Thus, after cooling to such an extent that solidifying temperature of the reaction solution is not achieved, toluene, hexane or the like is added thereto to suppress the solidifying property at room temperature and then the mixture is mixed with a poor solvent for the semiconductor nanoparticles such as lower alcohol (e.g., methanol, ethanol, n-propanol, isopropyl alcohol or n-butanol) or water followed by subjecting to a physical means such as centrifugal separation or decantation to separate. The separated product prepared as such is dissolved in toluene, hexane or the like again and the processes of isolation and separation are repeated whereby it is possible to further improve the purity. The solvent for the precipitation may be a mixed solvent.

Attachment of the poly(alkylene glycol) Residue to the Surface of Semiconductor Crystals

There is no limitation for a method for attaching poly(alkylene glycol) to the semiconductor crystals prepared by any of the above-exemplified manufacturing methods utilizing the above-mentioned coordination structure represented by mercapto group or phosphine oxide group. An example is a method where poly(alkylene glycol) having a mercapto group (hereinafter, abbreviated as PAG-SH) is coordinated on the surface of the semiconductor crystals and, to be more specific, a ligand exchange reaction where the semiconductor nanoparticles having coordination organic compound such as TOPO prepared in the above hot soap method on the surface are contacted to PAG-SH in a liquid phase is possible. In that case, a solution using the solvent which will be mentioned later may be used if necessary and, when the PAG-SH used therefor is liquid under the reaction condition, a reaction manner where PAG-SH per se is used as a solvent and no other solvent is added is possible as well.

With regard to the condition for such a ligand exchange reaction, there are exemplified a method where it is carried out in alcohol such as methanol according to a method mentioned in X. Peng, et al.: Angew. Chem. Int. Ed. Engl., volume 36, page 145 (1997); a method where it is carried out in a mixed solvent of dimethyl sulfoxide with alcohol such as methanol according to a method mentioned in M. Bruchez, Jr. et al.: Science, volume 281, page 2013 (1998); and a method where it is carried out in a halogenated solvent such as chloroform according to a method mentioned in C. W. Warren, et al.: Science, volume 281, page 2016 (1998). Moreover, as reported in the above-mentioned X. Peng, et al.: J. Am. Chem. Soc., volume 119, page 7019 (1997), it is also possible to apply a method where semiconductor nanoparticles having a coordination organic compound such as trioctylphosphine oxide obtained by the above hot soap method on the surface are dispersed in a liquid phase containing a weakly coordinating compound such as pyridine (usually, it is used in a large excess as a solvent) and the said coordination organic compound is removed. Thus, it is a two-step reaction comprising the first step where a coordination organic compound is removed in a weakly coordination compound such as pyridine and the second step where PAG-SH is added thereto. In any of the methods, the reaction solution may be heated or vacuated if necessary.

With regard to the solvent used for such a ligand exchange reaction, there may be exemplified nitrogen-containing aromatic compounds such as pyridine, lutidine, collidine and quinoline; alkyl halides such as methylene chloride, chloroform, carbon tetrachloride and 1,2-dichloroethane; aromatic hydrocarbons such as benzene, toluene, xylene, naphthalene, chlorobenzene and dichlorobenzene; alkanes such as n-pentane, n-hexane, cyclohexane, n-octane and isooctane; aliphatic ethers such as diethyl ether and tetrahydrofuran; aliphatic ketones such as acetone and methyl ethyl ketone; solvents of an ester type such as methyl acetate and ethyl acetate; alcohols such as methanol, ethanol, n-propanol, isopropyl alcohol, n-butanol and ethylene glycol; phenols such as phenol and cresol; compounds having hydroxyl group such as water; primary amines having about 20 or less carbons such as butylamine, hexylamine, cyclohexylamine, octylamine, decylamine, dodecylamine, hexadecylamine, octadecylamine, phenylamine and aniline; secondary amines having about 20 or less carbons such as diethylamine, dibutylamino, dihexylamino, dioctylamine, dodecylamine, diphenylamine, methylphenylalanine, pyrrolidone, piperidine, morpholine and methylaniline; tertiary amines having about 20 or less carbons such as triethylamine, tributylamine, ethyl diisopropylamino, trihexylamine, phenyl dimethylamine, methyl diphenylamine, N-methylpyrrolidine, N-methylpiperidine, N-methylmorpholine and dimethylaniline; aprotic solvents of an amide type such as N,N-dimethylformamide (DMF), N,N-dimethylacetamide (DMAc) and N-methylpyrrolidone (NMP); sulfoxides such as dimethyl sulfoxide; and water. Solvents as such may be used in any type, combination and ratio depending upon the necessity of adjustment of solubility, etc. of the semiconductor nanoparticles and products thereof. It is also possible to use the above solvent to which acid or base is added.

When the amount of PAG-SH used is controlled in the above ligand exchange reaction, it is possible to attach a desired amount of PAG-SH to the surface of semiconductor crystals. As a result of control of attached amount of PAG-SH as such, it is possible to control hydrophilicity and water solubility of the semiconductor nanoparticles of the present invention. The attached amount of PAG-SH in the semiconductor nanoparticles of the present invention in terms of weight percentage (wt %) of the said nanoparticles in the organic components is usually from 0.1 wt % to 100 wt % and, in view of hydrophilicity, its lower limit is 1 wt % or more, more preferably 10 wt % or more and, most preferably, 20 wt % or more. The weight percentage can be estimated by a combination of various analytical means such as nucleomagnetic resonance spectrum (NMR), infrared absorption spectrum (IR), elementary analysis and thermogravimetric analysis (TG).

The above ligand exchange reaction is usually carried out within a temperature range of −10-250° C. and, for preventing the thermal deterioration of the organic compound and the unfinished exchange reaction, the temperature range is made preferably about 0-200° C., more preferably about 10-150° C. and, most preferably, about 20-120° C. With regard to the reaction time, that depends upon the material and temperature but, usually, it is from 1 minute to 100 hours, preferably from 5 minutes to 70 hours, more preferably from 10 minutes to 50 hours and, most preferably, from 10 minutes to 30 hours. Further, in the ligand exchange reaction as such, there is no limitation for the order of addition of the semiconductor nanoparticles and PAG-SH to the reaction solution.

In order to avoid the side reaction such as oxidation, it is preferred to carry out the ligand exchange reaction in an atmosphere of inert gas such as nitrogen and argon. Not only for such a ligand exchange reaction, there are also some cases where the after-treatment steps for the manufacture of the nanoparticles are carried out under shielding from the light.

In isolating the product after such a ligand exchange reaction, any purifying methods such as filtration, combination of precipitation and centrifugal separation, distillation and sublimation may be used and the particularly effective one is a combination of precipitation with centrifugal separation where the fact that specific gravity of semiconductor crystals is bigger than those of usual organic compounds. The centrifugal separation is carried out in such a manner that liquid containing a product of the ligand exchange reaction is poured over a poor solvent (an organic solvent containing hydrocarbon such as n-hexane, cyclohexane, heptane, octane or isooctane) for the semiconductor nanoparticles of the present invention to which PAG-SH is bonded and the suspension containing the resulting precipitate is subjected to centrifugal separation. The resulting precipitate is separated from the supernatant liquid by, for example, decantation and, if necessary, subjected to repeated washings with a solvent and re-dissolving as well as re-precipitation/centrifugal separation to improve the degree of purification. In the re-dissolving, there may be used a solvent such as aromatic hydrocarbons (e.g., toluene), lower alcohols having about 4 or more carbons (e.g., ethanol, isopropyl alcohol, n-butanol and tert-butyl alcohol), ketones (e.g., acetone), cyclic ethers (e.g., tetrahydrofuran), esters (e.g., ethyl acetate), water, etc. and any kinds thereof may be mixed and used. Revolution at the centrifugal separation is usually about 100-8,000 rpm, preferably about 300-6,000 rpm and, more preferably, about 500-4,000 rpm while the temperature is within a range of usually about −10-100° C., preferably about 0-80° C., more preferably about 10-70° C. and, most preferably, about 20-60° C. There are some cases that such a purifying step may be also carried out in the atmosphere of inert gas such as nitrogen or argon so as to avoid the side reaction such as oxidation.

Resin Composition

The semiconductor nanoparticles of the present invention may be used as a resin composition by dispersing into any resin matrix. Even in that case, any of the above-mentioned additives or the like may be added thereto. Although there is no particular limitation for the method of manufacturing the resin composition, a method where the semiconductor nanoparticles of the present invention are mixed with any resin by any of known methods and a method where the semiconductor nanoparticles are mixed with a monomer giving the desired resin matrix followed by conducting the polymerization reaction of the monomer may be usually and advantageously used.

With regard to a method where the semiconductor nanoparticles are mixed with a desired resin, there may be exemplified a fusion kneading and a solution blending.

With regard to a method for the fusion kneading, there may be exemplified a method where the above-exemplified thermoplastic resin pellets, powder, flakes, etc. are mixed with the semiconductor nanoparticle powder (dry blending), then poured into any fusion kneading machine such as uniaxial kneader, biaxial kneader, brabender, roll, labo plastomill, etc. and mixed with a thermoplastic resin which is fused by application of shearing at the temperature of the softening point of the said thermoplastic resin or higher. There is no particular limitation for the shape of the stirring mechanism such a screw used therefor and, for example, a screw block such as reversely rotating disk and kneading disk may be inserted for enhancing the shearing of the biaxial kneader for example. The resulting resin composition may be taken out in any shape such as strand, resin block, plate and pellet. During such a fusion kneading, there may be added water and/or an alcoholic solvent represented by methanol and, with an object of removal of volatile components, vacuation of the fusion kneading system (the so-called evacuation from a vent) may be carried out.

With regard to a method for the solution blending, there may be exemplified a method where the thermoplastic resin pellets, powder, flakes, etc. and the semiconductor nanoparticle powder or flakes are dissolved in an appropriate common solvent (representative ones are a solvent having hydroxyl group such as water and alcohol; nitrogen-containing aromatic compound such as pyridine; cyclic ether such as THF and 1,4-dioxane; alkyl halide such as methylene chloride and chloroform; aprotic polar solvent of an amide type such as DMF and NMP; etc.) and well mixed in the solvent and the solvent is removed by means of distillation or drying and a method where the solution is poured over a poor solvent such as cyclohexane to precipitate the resin composition. In dissolving as such, heating may be carried out if necessary. Distillation of the solvent may be carried out in vacuo. With regard to the solvent used for preparing the solution and the poor solvent used for the precipitation, plural types of solvents may be used.

On the other hand, with regard to a method where the semiconductor nanoparticles are mixed with a monomer giving any desired resin matrix and then the polymerization reaction of the monomer is carried out, it is common that, at first, the semiconductor nanoparticles are dissolved in an aromatic vinyl compound such as styrene, α-methylstyrene, p-chlorostyrene, p-methylstyrene, p-chloromethylstyrene, p-hydroxystyrene, p-acetoxystyrene, vinylnaphthalene, 2-vinylpyridine and 4-vinylpyridine; an acrylic acid or methacrylic acid derivative such as methyl acrylate, ethyl acrylate, butyl acrylate, benzyl acrylate, phenyl acrylate, isobomyl acrylate, methyl methacrylate, ethyl methacrylate, butyl methacrylate, hydroxyethyl methacrylate, benzyl methacrylate, phenyl methacrylate, norbornane methyl methacrylate, isobornyl methacrylate, adamantyl methacrylate, acrylamide, methacrylamide, acrylonitrile and methacrylonitrile; a vinyl ester such as vinyl acetate; a radical polymerizing monomer such as N-vinylpyrrolidone and N-vinyloxazoline; a cyclic ether such as THF, propylene oxide and epichlorohydrin; a cyclic amide such as ε-caprolactam; a cyclic ester such as ε-caprolactone and γ-butyrolactone; and other ring-opening polymerizing monomer; or a polymerizing monomer such as metal alkoxide (e.g., tetraethoxysilane) used for a hydrolyzing condensation (the so-called sol-gel method) and then a predetermined monomer polymerization reaction is carried out. At that time, an appropriate solvent may be used together.

If necessary, a cross-linking polyvalent monomer may be added to the above-mentioned monomer and its examples as a radically polymerizing cross-linking agent are an aromatic vinyl compound such as divinylbenzene, trivinylbenzene and divinylpyridine; bisacryloyloxyethane; pentaerythritol tetrakis(meth)acrylate; and pentaerythritol tris(meth)acrylate. In that case, there may be some cases where the resin composition loses its thermoplastic property.

In conducting a radical polymerization of such a radically polymerizing monomer in the presence of the semiconductor nanoparticles, a radical initiator is usually added. There is no limitation for the radical initiator which is able to be used here and, as a thermodegradable radical initiator, representative one is that which is soluble in the above radically polymerizing monomer such as an azo compound (e.g., azobisisobutyronitrile (AIBN)) and a peroxide (e.g., benzoyl peroxide and tert-butyl peroxide) although it is also possible to use a water-soluble radical generator such as a persulfate (e.g., sodium persulfate, potassium persulfate, lithium persulfate and ammonium persulfate). It is further possible to use a photodegradable radical initiator such as an aminoacetophenone (e.g., α-aminoacetophenone and 2-benzyl-2-dimethylamino-1-(4-morpholinophenyl)-butane-1) as well as a benzyldimethylketal, a glyoxy ester, an acylphosphineoxy, etc.

In the above-mentioned method for the manufacture of any desired resin composition, the semiconductor nanoparticles may be used in a form of the so-called master batch where they are previously contained in a high concentration in an appropriate organic substance. With regard to the matrix organic substance in the master batch as such, there may be used any thermoplastic resin, wax, solvent, any of the above-mentioned polymerizing monomer (including a cross-linking multivalent monomer), etc. Method for preparing such a master batch may be conducted by means of any of known methods such as the above-mentioned fusion kneading and solution blending.

In the manufacturing steps for the above-mentioned any desired resin composition, there are some cases where atmosphere of inert gas (such as dry nitrogen or argon) and shielding from light are preferred for suppressing the oxidation reaction by heat and light upon mixing the materials.

Thin Film

The semiconductor nanoparticles of the present invention are applicable to various uses after shaping by common methods and an example thereof is thin film.

Such a thin film can be prepared in such a manner that the semiconductor nanoparticles of the present invention prepared by the above-mentioned manufacturing method are dissolved or dispersed in an appropriate solvent (for example, an aromatic solvent such as toluene; a ketone solvent such as acetone; an ether solvent such as tetrahydrofuran; or a halogenated solvent such as chloroform, methylene chloride and chlorobenzene) and the solution or dispersion is applied by flowing on a desired substrate such as a glass substrate, an electroconductive substrate (e.g., indium dope tin oxide (usually called ITO), metal or graphite), a semiconductor substrate (e.g., silicone) and a resin substrate of an amorphous polyolefin (e.g., polymethyl methacrylate (PMMA), polystyrene and polycycloolefin) or an aromatic polycarbonate. With regard to the term “applied by flowing” used here, there may be exemplified a flowing method where spreading on a substrate is conducted using a bar coater, an applicator, a doctor blade, etc.; a dip method where a substrate is dipped in a material liquid followed by pulling out therefrom; a spin coat method where the material liquid is applied; and other known methods. Viscosity of the material liquid is usually 0.1-1,000 centipoise(s), preferably 0.5-500 centipoise(s) and, more preferably, 1-100 centipoise(s). Temperature for the formation of film is usually −10-150° C., preferably 0-120° C. and, more preferably, 10-100° C. Flowing rate in the flowing method is usually 0.1-1000 m/minute, preferably 0.5-700 m/minute and, more preferably, 1-500 m/minute. Revolutions in the spin coat method is usually 10-100,000 rpm, preferably 50-50,000 rpm and, more preferably, 100-10,000 rpm.

At that time, the poly(alkylene glycol) residue which is a ligand functions as a continuous matrix whereby the semiconductor crystals are made into such a state that they are hardly aggregated each other and there is prepared a stable coated film achieving the absorption and luminescence characteristics of the said semiconductor crystals. Thus, one of the characteristics of the semiconductor nanoparticles of the present invention is that, since a poly(alkylene glycol) residue is available on the surface thereof, a coated film having excellent transparency and mechanical strength is resulted by itself even when an organic binder component such as resin is not jointly used.

During the shaping by such an application by way of flowing, it is also possible that an appropriate organic binder component such as resin (e.g. polymethyl methacrylate (PMMA), polystyrene or aromatic polycarbonate), wax, silicone fat/oil or the like is previously dissolved into a solvent. Amount of the organic binder in that case to the sum thereof with the nanoparticles is usually from 0% by weight to 90% by weight and, in view of mechanical strength and optical characteristics such as luminance, absorbance and light transmittance of the film, the lower limit is preferably 5% by weight or more, more preferably 10% by weight or more and, most preferably, 15% by weight or more while the upper limit is preferably 80% by weight or less, more preferably 70% by weight or less and, most preferably, 60% by weight or less.

It is further possible to add any of additives such as thermostabilizers, absorbers of light such as ultraviolet rays, antioxidants, oxygen scavengers and moisture absorbers to the thin film of the present invention so far as the advantage thereof is not significantly deteriorated.

The thin film may be shaped in a plane surface or in a curved surface having any curvature. Although there is no particular limitation for thickness, it is for example from 0.003 μm to 5,000 μm and, in view of luminance, absorbance or light transmittance, its lower limit is preferably 0.004 μm or more and, more preferably, 0.005 μm or more while its upper limit is preferably 1,000 μm or less, more preferably 500 μm or less and, still more preferably, 100 μm or less.

It is also possible that one or both side(s) of the thin film is/are installed, if necessary, with a layer having additional functions (such as protective layer against mechanical damage, gas barrier layer, light shielding layer, heat insulating layer and electrode layer).

The above-mentioned thin film of the present invention is useful in industry as an optical material such as a planar luminescent substance used for display, illumination instrument, etc. where luminescent characteristic of the nanoparticles is utilized, a super resolution layer or an ultraviolet absorbing film where absorption characteristic thereof is utilized or a high-density recording layer where absorption and luminescence characteristics thereof are utilized.

Optical Materials

The semiconductor nanoparticles of the present invention are able to be utilized as various optical materials by, for example, making into thin film or bulk-shaped substance. Uses as particularly important optical materials will be illustrated as follows.

1) Super Resolution Film

As a result of making the nanoparticles of the present invention into a form of thin film, they are used as a super resolution film which is installed in optical recording media such as an optical disk by utilization of saturated absorption characteristic of semiconductor crystal particles contained therein. The term “super resolution” used in the present invention means a technical concept that, in reading-out and writing-in of data (hereinafter, abbreviated as “reading and writing of data”) in an optical disk for example, its degree of resolution or, in other words, area of the unit recording region is made smaller than the original diameter of incident beam used for reading and writing of data so that improvement in the recording density is achieved.

The above-mentioned saturated absorption characteristic means a characteristic that, when light of a specific wavelength (hereinafter, referred to as “light of incidence”) which is absorbed by the above semiconductor crystal particles is applied, absorbance of the semiconductor crystals at the specific wavelength decreases as a result of an increase in intensity of the incident light. Quantitatively, such a saturated absorption characteristic is understood as a phenomenon that, as a result of an increase in intensity of the incident light (in other words, an increase in photon numbers in the incident light), excitation frequency of electron to excitation level participating in absorption of light increases whereby possibility of existence of electrons of the excitation level increases as well and, as a result, possibility of transfer of electrons to the excitation level decreases. When intensity of the incident light is sufficiently high, there is supposed a state where light absorption does not substantially take place any more and, therefore, such a phenomenon is called “saturated absorption”.

When the semiconductor nanoparticles of the present invention are applied to thin film, absorbance of the thin film at the desired incident light wavelength is made usually 0.1 or more, preferably 0.3 or more and, more preferably, 0.5 or more. The absorbance value is measured in such a manner that, in a thin film of 23° C., incident light of intensity of usually about 0.3 mW or less or, preferably, 0.1 mW or less is applied from the direction of normal line of the surface of the film.

Although there is no limitation for the thickness of the thin film so far as an effective saturated absorption can be detected, its lower limit is usually 50 nm or more, preferably 100 nm or more and, more preferably, 150 nm or more while its upper limit is usually 10,000 nm or less, preferably 5,000 nm or less and, more preferably, 3,000 nm or less where distribution of the thickness is preferably to be as little as possible. It is preferred that the surface of the film is as smooth as possible for suppressing the light scattering.

The semiconductor crystal particles which are advantageously used for application of the thin film of the present invention to the super solution film are CdS and ZnSe as mentioned already. When they are made in particles of a core-shell type where shell of semiconductor crystals having a big band gap such as in the case of ZnS, there are some cases where behavior of exciton absorption on the basis of quantum effect is stabilized and that is preferred. Content of the semiconductor crystal particles in the super resolution film is usually from 10% by volume to 60% by volume and, in view of the detective property of the saturated absorption and mechanical property of the film, the lower limit is made preferably 20% by volume or more and, more preferably, 25% by volume or more while the upper limit is made preferably 55% by volume or less or, more preferably, 50% by volume or less.

(2) Filter

By making into thin film, the nanoparticles of the present invention are able to be utilized as a filter by utilization of transparency and light absorption characteristic of the semiconductor crystal particles contained therein. In the semiconductor nanoparticles, light absorption wavelength can be changed depending upon their particle size and, therefore, it is possible to prepare a filter where the light absorption wavelength is precisely controlled. Since such a filter is able to take out the light of a specific wavelength region only, it is used as a color filter for display. With regard to semiconductor crystal particles suitable for such an object, there are exemplified cadmium selenide (CdSe) and cadmium sulfide (CdS). When ultraviolet ray is to be absorbed, it is used, for example, by closely adhering and shaping on the surface of transparent material where ultraviolet ray such as sunlight is absorbed to suppress or shield the transmittance such as window glass of automobiles, airplanes and buildings or lens of sunglasses, etc. With regard to the semiconductor crystal particles suitable for such an object, there are exemplified the above-mentioned titanium oxide, zirconium oxide (ZrO₂), zinc oxide (ZnO) and zinc sulfide (ZnS) where the wavelength at the absorption edge on the long-wavelength side of its absorption spectrum is 400 nm or less.

In view of a light absorbing ability, although it is preferred that the content of the semiconductor crystal particles in the thin film is as much as possible, it is usually from 10% by volume to 60% by volume and, in view of ultraviolet absorbing ability and mechanical strength of the film, the lower limit is made preferably 20% by volume or more or, more preferably, 30% by volume or more while the upper limit is made preferably 55% by volume or less or, more preferably, 50% by volume or less. When the content of the semiconductor particles in the thin film becomes big, there is noted another characteristic that hardness as the filter becomes high and, therefore, it is suitable when surface hardness is needed for window glass or lenses.

Although there is no limitation for the thickness of such a filter so far as an effective ultraviolet absorbing ability is achieved, the lower limit is made usually 0.05 μm or more, preferably 0.1 μm or more and, more preferably, 0.5 μm or more while the upper limit is made usually 2,000 μm or less, preferably 1,000 μm or less and, more preferably, 500 μm or less. Distribution of the thickness may be freely designed depending upon the function of the aimed transparent material. It is preferred that surface of the film is as smooth as possible for suppressing the reduction in light transmittance by light scattering but, depending upon the object, an appropriate unevenness may be applied thereto.

(3) Anti-Reflection Film

When the semiconductor nanoparticles of the present invention are made into thin film, they are utilized as an anti-reflection film utilizing the transparency and the high refractive index of the semiconductor crystal particles contained therein. Such an anti-reflection film is installed on the surface of the transparent material such as display panel, lens, prism or window glass whereupon there is achieved an effect of suppression, etc. of the light reflection at the surface of the said transparent material. With regard to the semiconductor crystal particles suitable for such an object, there are exemplified the above-mentioned titanium oxide, zirconium oxide (ZrO₂), zinc oxide (ZnO) and zinc sulfide (ZnS).

In view of making the refractive index of the thin film high, although it is preferred that the content of the semiconductor crystal particles in the thin film is as high as possible, it is usually from 10% by volume to 60% by volume and, in view of making refractive index high and also of mechanical strength of the film, the lower limit is made preferably 15% by volume or more and, more preferably, 20% by volume or more while the upper limit is made usually 50% by volume or less or, preferably, 45% by volume or less. Practically, refractive index of the thin film at 23° C. at the wavelength of D line of sodium is made usually 1.6 or more, preferably 1.7 or more, more preferably 1.8 or more and, most preferably 1.9 or more. Incidentally, when the content of the semiconductor particles in the above thin film becomes high, there is achieved another characteristic that hardness as the anti-reflection film becomes high and, therefore, it is suitable when the surface hardness of the above-mentioned transparent material is necessary.

On the surface of the anti-reflection film of the present invention, there may be installed a film comprising a material having a relatively low refractive index such as PMMA or silica. When such a film of low refractive index is installed, there are some cases where an excellent reflection-preventing function is achieved and that is suitable. Especially when it is formed on the surface of silica film, the resulting function as a layer having a protective function due to the excellent surface hardness against mechanical force from outside (such as abrasion and scratch) is useful.

Although there is no limitation for the thickness of the anti-reflection film so far as an effective anti-reflection ability is achieved, the upper limit is made usually 0.05 μm or more, preferably 0.1 μm or more and, more preferably, 0.2 μm or more while the upper limit is made usually 500 μm or less, preferably 100 μm or less and, more preferably, 10 μm or less. Distribution of the said film thickness may be freely designed depending upon the function of the aimed transparent material. Although it is preferred that the surface of the film is usually as smooth as possible for suppressing the reduction in light transmittance by light scattering, it is also possible to form an appropriate unevenness depending upon an object.

(4) Optical Waveguide

The nanoparticles of the present invention are used as an optical waveguide utilizing their transparency and high refractive index, etc. of the semiconductor crystal particles contained therein. The optical waveguide as such is used as an optical connector and an optical amplifier in optical telecommunication. Refractive index of the optical waveguide according to the present invention at the wavelength of D line of sodium at 23° C. is usually made 1.6 or more and, therefore, it is now possible that a commonly used resin material such as PMMA (refractive index: 1.49) is easily applied by making into rods or thin film by, for example, a solution application method without the use of expensive resin containing fluorine atoms or the like as a clad material. Refractive index of the optical waveguide is made preferably 1.7 or more and, more preferably, 1.75 or more.

With regard to the semiconductor crystal particles which are advantageous for such an object, there are exemplified the above-mentioned titanium oxides, zirconium oxide (ZrO₂), zinc oxide (ZnO) and zinc sulfide (ZnS). In view of making the refractive index of the shaped product high, although it is preferred that the content of the semiconductor particles in the shaped product is as high as possible, it is made usually from 10% by volume to 60% by volume and, in view of making the refractive index high and also of mechanical strength of the film, the lower limit is made preferably 15% by volume or more and, more preferably, 20% by volume or more while the upper limit is made usually 55% by volume or less or, more preferably, 50% by volume or less.

(5) Emitting Layer of Electroluminescent Device

The nanoparticles of the present invention are used as an emitting layer of electroluminescent device (EL device) utilizing their transparency and the emission spectrum inherent to the semiconductor crystal particles contained therein. The EL device has many excellent characteristics such as high-intensity luminescence, quick response, wide visual angle, thin shape with reduced weight and high resolution and is applied, for example, to a flat panel display. Therefore, it is preferred that its emitting layer is transparent, so that reduction in the emitting efficiency by scattering or the like does not result, and contains the semiconductor crystals in a high density. Accordingly, with regard to the semiconductor crystal particles containing an emitting layer used for such uses, there are exemplified the above-mentioned cadmium selenide (CdSe), zinc selenide (ZnSe), zinc oxide (ZnO), cadmium sulfide (CdS) and indium phosphide (InP) giving an emission spectrum within ultraviolet to near-infrared wavelength regions.

Although there is no limitation for the thickness so far as an effective emitting ability is achieved when the semiconductor nanoparticles of the present invention are used as an emission layer for an EL device by making into thin film, the lower limit is made usually 5 nm or more, preferably 20 nm or more and, more preferably, 50 nm or more while the upper limit is made usually 10,000 nm or less, preferably 2,000 nm or less and, more preferably, 500 nm or less. With regard to the content of the semiconductor crystals in the emitting layer, the lower limit is made usually 10% by volume or more, preferably 20% by volume or more and, more preferably, 25% by volume or more while the upper limit is made usually 60% by volume or less, preferably 55% by volume or less and, more preferably, 50% by volume or less.

Coating Material

The semiconductor nanoparticles of the present invention can be used as a material for aqueous or alcoholic coating materials utilizing their hydrophilicity. The term “aqueous coating material” used here means a coating material where water or a water-containing mixed solvent (hereinafter, referred to as aqueous solvent) is used as a solvent. A preferred mixed solvent in view of non-toxicity is a mixture of water with ethanol and the content of water therein is preferably 30% by weight or more or, more preferably, 50% by weight or more. When the aqueous solvent is removed from the coated film, the aqueous coating material containing the semiconductor nanoparticles of the present invention functions as a continuous matrix in which the state where the poly(alkylene glycol) residue which is a ligand makes the semiconductor crystals hardly aggregated each other giving a stable coated film which achieves the absorption and luminescence characteristics of the semiconductor crystals and that is useful. In that case, it is also possible that any of additives such as hydrophilic resin such as polyvinyl alcohol (PVA), ethylene-vinyl alcohol copolymer (EVOH) or polyethylene oxide (PEO), ultraviolet absorber, antioxidant, antiseptic agent, antifungal agent, dye, pigment or filler such as glass fiber, glass flakes or glass beads is mixed therewith.

Biological Analytic Reagent

Poly(alkylene glycol) residue has not only a high hydrophilicity but also an excellent “stealth property” that it is hardly recognized in vivo as a foreign substance or a physiologically active structure and, therefore, it is effectively utilized for surface treatment for materials which are necessary to contact to biological samples such as artificial organs and various biological analytical medical instruments. The semiconductor nanoparticles of the present invention has poly(alkylene glycol) residues on the surface thereof. Therefore, since they have both of those characteristics, when the surface is attached to molecules achieving a certain substrate-specific affinity to the surface (for example, protein such as antigen and antibody, protein, oligopeptide, polysaccharide, nucleic acid, epitope, avidins such as avidin and streptavidin and biotin), there results a characteristic preferred as a biological analytical reagent that the substrate-specific affinity is achieved without being disturbed because of the above-mentioned “stealth property”.

Although there is no limitation for a method of attaching the above-mentioned molecule having a substrate-specific affinity besides a poly(alkylene glycol) residue onto the surface of the semiconductor nanoparticles of the present invention, it is also possible that, for example, a “linking agent” having a functional group reactive to the molecule achieving the substrate-specific affinity (such as carboxyl group, amino group and maleoyl group) is previously fixed on the surface. With regard to the attached amount of the molecule having such a substrate-specific affinity to the total organic components including the poly(alkylene glycol) residue, etc., its lower limit is usually 5% by weight or more, preferably 10% by weight or more and, more preferably, 15% by weight or more while its upper limit is usually 90% by weight or less, preferably 80% by weight or less and, more preferably, 70% by weight or less.

A specific method for utilizing as a biological analytical reagent as such is a substrate-specific analytical method where the semiconductor nanoparticles of the present invention are contacted in liquid to a liquid sample containing the substrate to be analyzed and then the semiconductor nanoparticles bonded to the substrate to be analyzed are measured. Such quantitative analysis is usually carried out by an optical measurement where the absorption and luminescence characteristics of the semiconductor nanoparticles of the present invention are utilized and the preferred one in terms of sensitivity is measurement of luminescence while the preferred in terms of simplicity of the device is measurement of absorption. Quantitative analysis is also utilized for measuring detection of semiconductor nanoparticles having a high refractive index. There is no particular limitation for such a substrate-specific analytical method. For example, there are applicable a method where the semiconductor nanoparticles of the present invention are mixed with and contacted to the analytical sample liquid in a state of solution and a method where the semiconductor nanoparticles are previously fixed on the surface of an appropriate solid substrate (such as particles, fiber, glass substrate, metal substrate or resin substrate) and then the solid substrate surface is contacted to the analytical sample liquid.

### EXAMPLES

As hereunder, embodiments of the present invention will be illustrated in more detail by way of the Examples although the present invention is not limited to those Examples provided that the outcome is outside the gist of the present invention.

With regard to the material reagents, commercially available reagents were used without purification unless otherwise mentioned although the commercially available solvents were made into pure solvents by means of the following purifying operations.

Pure toluene: Toluene was washed with concentrated sulfuric acid, water, saturated aqueous solution of sodium bicarbonate and water in this order, dried over anhydrous magnesium sulfate, filtered through a filter paper and distilled at an atmospheric pressure after addition of diphosphorus pentaoxide (P₂O₅).

Pure methanol: Methanol was dried over calcium sulfate and calcium hydride and directly distilled at an atmospheric pressure after addition of sodium hydride; or methanol of an anhydrous grade supplied from Aldrich was used.

Pure methylene chloride: After drying over diphosphorus pentaoxide, a direct distillation at an atmospheric pressure was carried out.

Device, Condition, etc. for the Measurement

(1) Nuclear magnetic resonance (NMR) spectrum: JNM-EX270 type FT-NMR manufactured by JEOL (¹H: 270 MHz, ¹³C: 67.8 MHz). Unless otherwise mentioned, deuterated chloroform was used as a solvent and the measurement was carried out at 23° C. using tetramethylsilane as a 0 ppm control.

(2) Infrared absorption (IR) spectrum: FT/IR-8000 type FT-IR manufactured by JASCO. Measurement was carried out at 23° C.

(3) X-ray diffraction (XRD) spectrum: RINT 1500 manufactured by Rigaku K. K. (X-ray source: copper Kα line, wavelength 1.5418 Å). Measurement was carried out at 23° C.

(4) Observation under a transmission electron microscope (TEM): This was carried out using a transmission electron microscope of type H-9000 UHR manufactured by Hitachi (accelerating voltage: 30 kV; degree of vacuum during the observation: about 7.6×10⁻⁹ Torr).

(5) Photoluminescence (PL) spectrum: Measurement was carried out using a spectrophotofluorometer of type F-2500 manufactured by Hitachi under the conditions that 60 nm/minute of scanning speed, 5 nm of slit at the excited side, 5 nm of slit at the fluorescence side and 400 V of photomultiplier voltage at room temperature using a cell made of quartz having an optical path length of 1 cm.

(6) Absorption spectrum: Measurement was carried out at room temperature by an ultraviolet/visible absorptiometer of type HP 8453 manufactured by Hewlett-Packard using a cell made of quartz.

(7) Thermogravimetry (TG): This was carried out using TG-DTA 320 manufactured by Seiko Instruments K. K. on an aluminum plate in a nitrogen stream of 200 mL/minute under the conditions that the temperatrure-rising rate was 10° C./minute and the temperature was kept at 140° C. for 30 minutes and then at the highest set temperature of 590° C. (the actual measured temperature immediately beneath the sample was about 602-603° C.) for 60-120 minutes.

(8) Measurement of film thickness: This was carried out using a surface profiler P-15 (for checking roughness and fine shape of surface and cross section) manufactured by KLA Tencor under the conditions that scanning length was 10-20 mm, scanning speed was 0.2 mm/second and needle pressure was 0.2-2.0 mg.

### Synthetic Example 1

Synthesis of CdS Nanocrystals

Trioctyl phosphine oxide (hereinafter, abbreviated as TOPO; Strem Chemical; purity: 90%; 13 g) was placed in a four-necked flask made of colorless and transparent Pyrex® glass equipped with an air-cooling Liebig condenser and a thermocouple for adjusting the reaction temperature, subjected to an argon flowing for 30 minutes so that the inner volume was substituted with argon and heated at 300° C. with stirring using a magnetic stirrer. In the meanwhile, a material solution where dimethyl cadmium (Strem Chemical; a 10 wt % solution in n-hexane; 1.12 g) and bis(trimethylsilyl) sulfide (Fluka; 0.066 mL) were dissolved in tributyl phosphine (hereinafter, abbreviated as TBP; Strem Chemical; 5.1 g) in a glove box of a dry nitrogen atmosphere was prepared in a light-shielded glass bottle which was sealed by a rubber stopper (Septum supplied from Aldrich) and packed with aluminum foil without any aperture. The material solution (6 mL) was subjected to a single continuous injection using an injector into the above flask in which TOPO was charged and that stage was defined as the starting time for the reaction. The reaction was carried out shielding from light by covering the flask and the condenser with aluminum foil. After 20 minutes from the start of the reaction, the heat source was removed and, when the solution was cooled down to about 50° C., anhydrous methanol (Aldrich; Anhydrous; 1.4 mL) was injected thereinto followed by further cooling down to room temperature. The reaction solution was dropped into anhydrous methanol (45 mL) in a nitrogen atmosphere and stirred for 5 minutes to give a yellow insoluble substance. The insoluble substance was centrifuged (at 3,500 rpm) and separated therefrom by removing the supernatant liquid by means of decantation to give solid powder. The solid powder was dissolved in pure toluene (2 mL), injected into anhydrous methanol (30 mL), stirred at room temperature for 5 minutes and subjected to the same centrifugal separation and decantation as above to separate a solid precipitate. The precipitate was dried in vacuo and dried for one night at room temperature in vacuo to give yellow solid powder (hereinafter, abbreviated as CdS-TOPO; 85.2 mg).

The yellow solid powder prepared as such was dissolved in toluene and its absorption spectrum was measured whereupon a peak wavelength was observed at 404 nm. When its emission spectrum was measured (excitation light: 366 nm), two emission bands having peak wavelengths of 435.5 nm and 523.5 nm were observed.

### Synthetic Example 2

Synthesis of CdSe Nanocrystals

TOPO (6 g) was placed in a colorless and transparent four-necked flask made of Pyrex® glass equipped with an air-cooling Liebig condenser and a thermocouple for adjusting the reaction temperature, subjected to an argon flowing for 30 minutes so that the inner volume was substituted with argon and heated at 350° C. with stirring by a magnetic stirrer. In the meanwhile, a material solution where dimethyl cadmium (2.18 g) was mixed with and dissolved in a liquid where selenium (black powder of a single substance; Aldrich; 0.1 g) was dissolved in TBP (5.38 g) in a glove box of a dry nitrogen atmosphere was prepared in a light-shielded glass bottle which was sealed by a rubber stopper and packed with aluminum foil without any aperture. The material solution (3 mL) was subjected to a single continuous injection using an injector into the above flask in which TOPO was charged and that stage was defined as the starting time for the reaction. Immediately after the injection, the temperature was set at 300° C. and, after 10 minutes from the start of the reaction, the heat source was removed. When the solution was cooled down to about 60° C., anhydrous methanol (15 mL) was injected to give an insoluble substance. The insoluble substance was centrifuged (at 3,000 rpm) and separated therefrom by removing the supernatant liquid by means of decantation to give solid powder. The solid powder was dissolved in pure toluene (3 mL), injected into anhydrous methanol (30 mL), stirred at room temperature for 5 minutes and subjected to the same centrifugal separation and decantation as above to separate a solid precipitate. The solid was dried at room temperature, then dried in vacuo in a nitrogen stream and dried for one night at room temperature in vacuo to give red solid powder (hereinafter, abbreviated as CdSe-TOPO; 99.6 mg).

The red solid powder prepared as such was dissolved in toluene and its absorption spectrum was measured whereupon a peak wavelength was observed at 536 nm. When its emission spectrum was measured (excitation light: 366 nm), an emission band (peak wavelength: 549.5 nm) was observed.

### Synthetic Example 3

Synthesis of ZnO Nanocrystals

Nanoparticles of ZnO were synthesized by a method mentioned in J. Phys. Chem. B, volume 102, 5566-5572 (1998). To a colorless and transparent four-necked flask made of Pyrex® glass were added zinc acetate dihydrate (Kanto Kagaku K. K.; 0.2219 g) and ethanol (Junsei Chemical K. K.; 10 mL) followed by heating at 90° C. for 5 minutes whereupon zinc acetate was completely dissolved and the solution became colorless and transparent. When the solution was cooled at 0° C. using an ice bath, the solution became turbid as the temperature lowered. A solution which was prepared by dissolving lithium hydroxide monohydrate (Kishida Chemical; 0.0586 g) in ethanol (10 mL) together with applying ultrasonic wave and preserved at 0° c. was slowly dropped thereinto. When several milliliters were dropped, the solution became colorless and transparent. After all of the solution was dropped, the mixture was stirred at room temperature for 1 hour. When n-hexane (40 mL) was added thereto, turbidity was resulted and a white precipitate was obtained by centrifugal separation (3,000 rpm). The white precipitate was suspended (being unable to be dissolved) in ethanol (6 mL), n-hexane (12 mL) was added thereto and a white precipitate was recovered by a centrifugal separation (3,000 rpm) and dried by a nitrogen flow to give a white solid (67.7 mg). This white solid was, however, hardly dissolved in organic solvents such as toluene, chloroform and ethanol.

### Example 1

Synthesis of 10-phosphonodecyl MTEG Ether

Sodium hydride in oil (Wako Pure Chemical; 741.6 mg) was placed in a flask and, after the inner area of the container was substituted with argon, triethylene glycol monomethyl ether (hereinafter, abbreviated as MTEG; TCI K. K.; 1.27 g) and distilled N,N-dimethylformamide (10 mL) were added thereto and mixed therewith in an argon stream followed by stirring at room temperature for 30 minutes at room temperature. The flask was transferred onto a cold water bath, 1,10-dibromodecane (TCI K. K.; 9 mL) was added thereto and the mixture was stirred at room temperature for 3.5 hours and allowed to stand for one night at room temperature. Methanol (Junsei Chemical K. K.; 3 mL) was added to the reaction mixture and, after stirring at room temperature for 30 minutes, it was concentrated in vacuo. To the reaction mixture after concentration was added methylene chloride (Junsei Chemical K. K.; 100 mL) and the organic layer was washed with water, dried over magnesium sulfate, filtered, concentrated and dried at room temperature in vacuo to give a crude product. The crude product was purified by a silica gel chromatography of an n-hexane-ethyl acetate type to give 10-bromodecyl MTEG ether.

10-Bromodecyl MTEG ether (382.4 mg) was placed in a flask, the inner area of the container was substituted with argon, tris(trimethylsilyl) phosphite (Tokyo Kasei K. K.; 1.05 g) was added thereto and mixed therewith in an argon stream, the mixture was stirred at 120° C. for 13.5 hours and cooled at 85° C. with stirring, an excessive tris(trimethylsilyl) phosphite was removed in vacuo and, when no decrease in the amount of the reaction mixture was noted, the mixture was cooled down to room temperature. The inner area of the container was returned to atmospheric pressure using argon and a 5:1 mixture (ratio by volume; 3.2 mL) of tetrahydrofuran and water was added thereto followed by stirring at room temperature for 3 hours and by stirring in vacuo for 1 hour more. Chloroform was added to the remaining reaction mixture to extract, the extract was passed through a column of silica gel (amount of silica gel: 0.09 g) and the column was washed with chloroform. The extract and the washing liquid passing through the column were combined and concentrated in vacuo, ethanol was added to the residue to dissolve therein and the solution was concentrated in vacuo once again. To the residue was added ethyl acetate to dissolve and the solution was concentrated in vacuo once again and dried at room temperature in vacuo (351.6 mg).

The product gave absorption bands in an IR spectrum at 2750 cm⁻¹, 2363 cm⁻¹, 1199 cm⁻¹ and 1018 cm⁻¹ assigned to a phosphonic acid structure, at 1107 cm⁻¹ assigned to an ether structure derived from MTEG and at 2928 cm⁻¹ and 2856 cm⁻¹ assigned to a hydrocarbon structure derived from MTEG and alkylphosphonic acid. In addition, in ¹H-NMR, the product gave rational signal and integral value corresponding to the expected structure as will be mentioned later and, therefore, it was concluded that 10-phosphonodecyl MTEG ether (hereinafter, abbreviated as MTEG-C10PA) was isolated.

¹H-NMR spectrum: 1.16-1.84 (multiplet, 18 protons, phosphonic acid aliphatic chain), 3.35 (singlet, 3 protons, methyl group), 3.42 (triplet, 2 protons, J=6.6 Hz, methylene group at the side of phosphonic acid adjacent to ether bond), 3.50-3.70 (multiplet, 12 protons), 8.86 (broad singlet, 2 protons, hydroxyl group derived from phosphonic acid).

### Example 2

Synthesis of CdS Nanoparticles Coordinated with MTEG-C10PA

CdS-TOPO obtained by the operation mentioned in Synthetic Example 1 was further purified by toluene and ethanol for three times so that MTEG-C10PA synthesized in Example 1 was apt to be coordinated. After that, ethanol (5 mL) was added to CdS-TOPO (0.0194 g) and MTEG-C10PA (0.01 g) and the mixture was heated to reflux for about 4 hours with stirring in an argon atmosphere. As a result of this heating to reflux, the semiconductor nanocrystals of Synthetic Example 1 were dissolved to give a yellow ethanolic solution without turbidity. To the residue obtained by concentration of the reaction solution in vacuo was added n-hexane (20 mL), ultrasonic wave was irradiated for about 20 seconds to disperse and then insoluble substance was separated by means of centrifugal separation (at 3,000 rpm for 6 minutes) and decantation. The insoluble substance separated as such was dissolved again in toluene (0.5 mL), then n-hexane (20 mL) was added to generate an isolated substance and it was separated by means of centrifugal separation and decantation as same as above. Such operations of re-dissolving, isolation and separation were repeated once again to purify. The precipitate prepared as such was dried at room temperature in vacuo to remove the solvent whereupon a yellow solid (16.9 mg) was obtained. The weight loss of this yellow solid during the TG measurement was 34%.

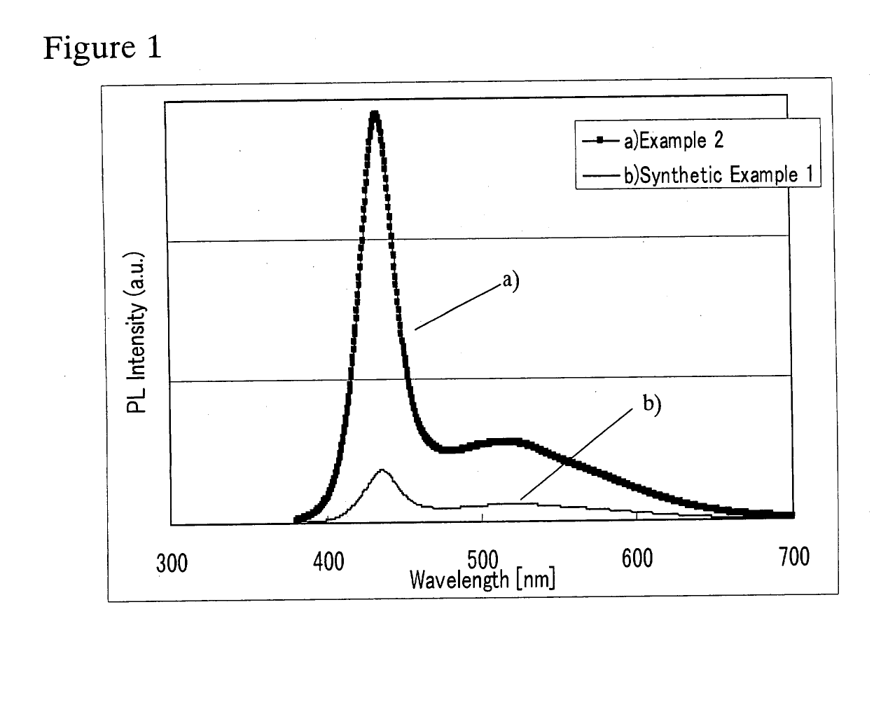

The yellow solid prepared as such was soluble in toluene, chloroform and tetrahydrofuran and was very well soluble even in acetone, N,N-dimethylformamide and ethyl acetate (in which CdS-TOPO is lowly soluble) and also soluble in ethanol and methanol (in which CdS-TOPO is hardly soluble) whereupon a yellow solution without turbidity was obtained. This is presumed to be due to the fact that MTEG-C10PA is coordinated on the surface of CdS crystals. Peak positions of absorption bands and emission bands were almost unchanged from those of CdS-TOPO before conducting the ligand exchange. However, when emission intensity was compared with CdS-TOPO having the same absorbance using the same toluene as a solvent, it was noted that, in the two emission bands of CdS nanoparticles coordinated with MTEG-C10PA, the peak emission intensity in the short wavelength was 7.9-fold and that in the long wavelength was 4.4-fold (excitation light=366 nm) (FIG. 1). Such increases in the emission intensity is presumed to be due to the fact that, as a result of coordination of MTEG-C10PA on the CdS nanocrystal surface, contribution of nonradiative process via surface state, etc. is suppressed.

When the yellow solid (1.5 mg) was dissolved in a mixture of toluene with chloroform (in a ratio of 1:1 by volume; 26 μL) and subjected to a spin coating (750 rpm) on a quartz substrate, a yellow coated film (film thickness: 180 nm) without turbidity was obtained and the resulting coated film gave the emission bands which were nearly same as those in the case of the solution.

### Example 3

Synthesis of CdSe Nanoparticles Coordinated with MTEG-C10PA

Ethanol (7.5 mL) was added to CdSe-TOPO (0.032 g) obtained by the operation mentioned in Synthetic Example 2 and MTEG-C10PA (0.0158 g) synthesized in Example 1 and the mixture was heated to reflux for about 5 hours with stirring in an argon atmosphere. As a result of this heating to reflux, the semiconductor nanocrystals of Synthetic Example 2 were dissolved to give a red ethanolic solution without turbidity. To the residue obtained by concentration of the reaction solution in vacuo was added n-hexane (30 mL), ultrasonic wave was irradiated for about 20 seconds to disperse and then an insoluble substance was separated by means of centrifugal separation (at 3,000 rpm for 6 minutes) and decantation. The insoluble substance separated as such was dissolved again in toluene (0.7 mL), the solution was injected into n-hexane (35 mL) to generate an isolated substance and it was separated by means of centrifugal separation and decantation as same as above. Such operations of re-dissolving, isolation and separation were repeated once again to purify. The precipitate prepared as such was dried at room temperature in vacuo to remove the solvent whereupon a red solid (30.8 mg) was obtained.

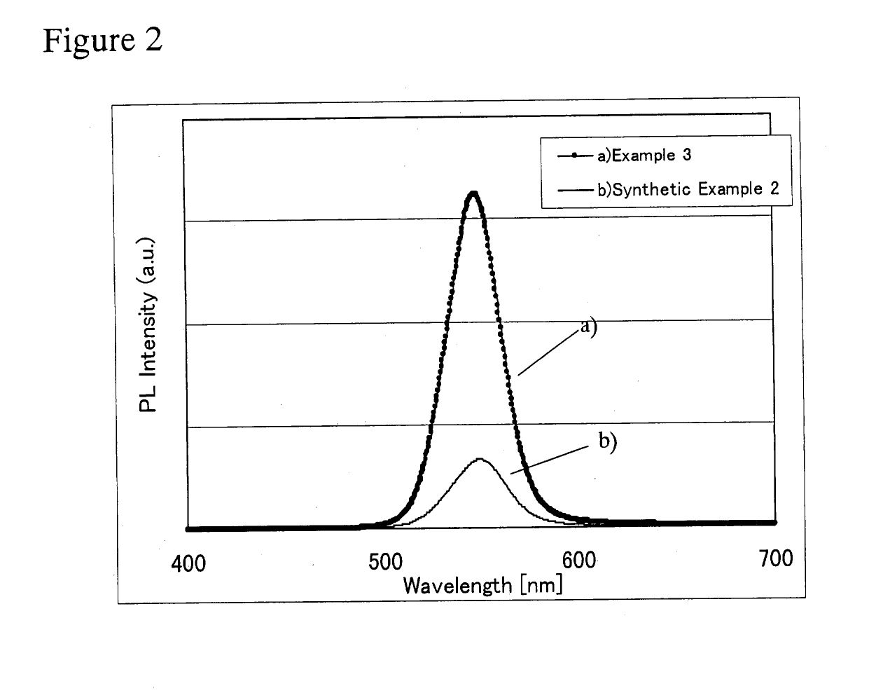

The red solid prepared as such was soluble in toluene, chloroform and tetrahydrofuran and was very well soluble even in acetone, N,N-dimethylformamide and ethyl acetate (in which CdSe-TOPO is lowly soluble) and also in ethanol and methanol (in which CdSe-TOPO is hardly soluble) whereupon a red solution without turbidity was obtained. This is presumed to be due to the fact that MTEG-C10PA is coordinated on the surface of CdSe crystals. Peak positions of absorption bands and emission bands were almost unchanged from those of CdSe-TOPO before conducting the ligand exchange. When emission intensity was compared with CdSe-TOPO having the same absorbance using the same toluene as a solvent, it was noted that the peak emission band of CdSe nanoparticles coordinated with MTEG-C10PA was increased to an extent of 4.9-fold (excitation light: 366 nm) (FIG. 2).

When the red solid (1.5 mg) was dissolved in a mixture of toluene with chloroform (in a ratio of 1:1 by volume; 26 μL) and subjected to a spin coating (750 rpm) on a quartz substrate, a red coated film (film thickness: 130 nm) without turbidity was obtained and the resulting coated film gave the emission bands which were nearly same as those in the case of the solution.

### Example 4

Synthesis of ZnO Nanoparticles Coordinated with MTEG-C10PA

Ethanol (5 mL) was added to ZnO (0.0202 g) obtained by the operation mentioned in Synthetic Example 3 and MTEG-C10PA (0.0209 g) synthesized in Example 1 and the mixture was heated to reflux for about 7 hours with stirring in an argon atmosphere. Since the solution was turbid even after heating to reflux, an insoluble substance was removed by means of centrifugal separation. This insoluble substance is supposed to be ZnO crystals in bulk generated in the synthesis of ZnO nanocrystals in Synthetic Example 3. To the residue obtained by concentration of the resulting colorless and transparent supernatant liquid in vacuo was added n-hexane (25 mL), ultrasonic wave was irradiated for about 20 seconds to disperse and then an insoluble substance was separated by means of centrifugal separation (at 3,000 rpm for 6 minutes) and decantation. The insoluble substance separated as such was dissolved again in toluene (1 mL) and n-hexane (25 mL) was added thereto to purify whereupon the isolated substance was produced. The precipitate prepared as such was dried at room temperature in vacuo to remove the solvent whereupon a white solid (24 mg) was obtained. The weight loss of the white solid during the TG measurement was 31%.

The white solid prepared as such was soluble in toluene, chloroform, ethanol, methanol, ethyl acetate, N,N-dimethyloformamide and tetrahydrofuran to give a colorless and transparent solution. This is presumed to be due to the fact that MTEG-C10PA is coordinated on the surface of ZnO nanocrystals. The peak position of absorption spectrum when dissolved in toluene was at 333 nm while the peak position of emission spectrum was at 522 nm.

When a solution of the white solid (2 mg) in chloroform (20 μL) subjected to a spin coating (500 rpm) on a quartz substrate, a colorless coated film (film thickness: 500 nm) without turbidity was obtained and the resulting coated film gave the emission bands which were nearly as same as those in the case of the solution.

### Synthetic Example 4

Synthesis of CdSe Nanocrystals

TOPO (Strem Chemical; purity: 90%; 8 g) was placed in a three-necked flask made of colorless and transparent Pyrex glass equipped with an air-cooling Liebig condenser and a thermocouple for adjusting the reaction temperature, subjected to an argon flowing for 30 minutes so that the inner volume was substituted with argon and heated at 350° C. with stirring using a magnetic stirrer. On the other hand, a material solution where dimethyl cadmium (Strem Chemical; 10 wt % n-hexane solution; 1.09 g) was mixed with and dissolved in a solution prepared by dissolving selenium (black powder of a single substance; Aldrich; 0.05 g) in TBP (Strem Chemical; 2.19 g) in a glove box in a dry nitrogen atmosphere was prepared in a light-shielded glass bottle which was sealed by a rubber stopper (Septum supplied from Aldrich) and packed with aluminum foil without any aperture. All of the material solution was subjected to a single continuous injection using an injector into the above flask in which TOPO was charged and that stage was defined as the starting time for the reaction. Immediately after the injection, the set temperature was made 300° C. and, after 20 minutes from the start of the reaction, the heat source was removed and, when the solution was cooled down to about 60° C., anhydrous methanol (Aldrich; Anhydrous; 20 mL) was injected to give an insoluble substance. The insoluble substance was centrifuged (at 3,000 rpm) and separated therefrom by removing the supernatant liquid by means of decantation to give solid powder. The solid powder was dissolved in pure toluene (2 mL), injected into anhydrous methanol (20 mL), stirred at room temperature for 5 minutes and subjected to the same centrifugal separation and decantation as above to separate a solid precipitate. The solid was dried in vacuo at room temperature in a dry nitrogen stream at room temperature and then dried at room temperature for one night in vacuo to give red solid powder (hereinafter, abbreviated as CdSe-TOPO; 120.5 mg).

The red solid powder prepared as such was dissolved in toluene and its absorption spectrum was measured whereupon a peak wavelength was observed at 546 nm. When its emission spectrum was measured (excitation light: 365 nm), a green emission band (peak wavelength: 557 nm) was resulted.

### Synthetic Example 5

Synthesis of CdSe Nanocrystals Having ZnS Shell

This was carried out according to a method mentioned in B. O. Dabbousi, et al.: J. Phys. Chem. B, volume 101, page 9463 (1997). That will be illustrated as hereunder.

TOPO (5 g) was placed in a three-necked flask made of brown glass equipped with an air-cooling Liebig condenser and a thermocouple for adjusting the reaction temperature and subjected to an argon flowing for 30 minutes so that the inner volume was substituted with argon. The temperature was set at 100° C. and solid powder of CdSe nanoparticles (0.030 g) obtained by the same method as in Synthetic Example 4, trioctyl phosphine (Aldrich; 0.5 g; hereinafter, abbreviated as TOP) and n-hexane (Junsei Kagaku; 0.5 ml) were added to give a transparent solution containing CdSe nanoparticles. This was stirred at 100° C. in vacuo for about 1 hour more, the temperature was set at 180° C. and the pressure was returned to atmospheric pressure with argon. In the meanwhile, a material solution by dissolving a 1N n-hexane solution of diethyl zinc (Aldrich; 0.45 mL; 0.45 mmol) and bis(trimethylsilyl) sulfide (Fluka; 0.0942 mL; 0.45 mmol) in TOP (9 mL) in a glove box of a dry nitrogen atmosphere was prepared in a glass bottle shielded from light by sealing with Septum and wrapped with aluminum foil without any aperture. The material solution was dropped into the above transparent solution of 180° C. containing the CdSe nanocrystals during 25 minutes, temperature was lowered to 90° C. and stirring was continued for about 3 hours more. After it was allowed to stand at room temperature for about 60 hours, it was heated again with stirring at 90° C. for 4 hours. The heat source was removed, anhydrous n-butanol (Aldrich; 2 mL) was added to the reaction solution and the mixture was cooled down to room temperature. The reaction solution was dropped into anhydrous methanol (30 mL) and stirred for 5 minutes to give a red insoluble substance. This red insoluble substance was separated by means of centrifugal separation and decantation by the same manner as in Synthetic Example 4 and dissolved in pure toluene (2 mL). The toluene solution was injected into a mixed liquid of anhydrous methanol and anhydrous n-butanol (in a ratio of 2/3 by volume) (20 mL) at room temperature, stirred for 5 minutes and centrifuged and the supernatant liquid was discarded by decantation to give red solid powder. The solid was dried at room temperature in a dry nitrogen stream and dried in vacuo at room temperature for one night to give red solid powder (hereinafter, abbreviated as CdSe/ZnS-TOPO; 44.2 mg).

The red solid powder prepared as such was dissolved in toluene and, when its absorption spectrum was measured, the peak wavelength was noted at 553 nm. When its emission spectrum was measured (excitation light: 365 nm), green emission band (peak wavelength: 568 nm) was noted. Since this emission showed clearly bigger emission intensity in the solution concentration of the same degree than the case of the CdSe nanoparticles before having ZnS shell, it was presumed that conversion to CdSe nanoparticles having ZnS shell took place and that contribution of non-emission process via surface level was suppressed.

### Synthetic Example 6

Synthesis of CdS Nanocrystals

TOPO (13 g) was placed in a three-necked flask made of colorless and transparent Pyrex glass equipped with an air-cooling Liebig condenser and a thermocouple for adjusting the reaction temperature and subjected to an argon flowing for 30 minutes so that the inner volume was substituted with argon followed by heating at 300° C. with stirring by a magnetic stirrer. On the other hand, a material solution by dissolving dimethyl cadmium (10 wt % n-hexane solution; 1.12 g) and bis(trimethylsiyl) sulfide (0.066 mL) in TBP (5.1 g) in a glove box of a dry nitrogen atmosphere was prepared in a glass bottle shielded from light by sealing with Septum and wrapped with aluminum foil without any aperture. This material solution (6 mL) was subjected to a single continuous injection using an injector into the above flask in which TOPO was placed and that stage was defined as the starting time of the reaction. The reaction was carried out under shielding from light by covering the flask and the condenser with aluminum foil. After 20 minutes from the start of the reaction, the heat source was removed and, when the solution was cooled down to about 50° C., anhydrous methanol (1.4 mL) was injected followed by cooling to room temperature. The reaction solution was dropped into anhydrous methanol (45 mL) in a nitrogen atmosphere and stirred for 5 minutes to give a yellow insoluble substance. This yellow insoluble substance was separated by means of centrifugal separation (3,500 rpm) and decantation to give solid powder. The solid powder was dissolved in toluene (2 mL), injected into anhydrous methanol (30 mL), stirred at room temperature for 5 minutes and subjected to centrifugal separation and decantation as mentioned above to separate a solid precipitate. This solid was dried at room temperature in a dry nitrogen atmosphere and dried in vacuo at room temperature for one night to give yellow solid powder (hereinafter, abbreviated as CdS-TOPO; 87.2 mg).

When the yellow solid powder prepared as such was dispersed in toluene and, when its absorption spectrum was measured, the peak wavelength was noted at 404 nm. When its emission spectrum was measured (excitation light: 366 nm), there were two emission bands having peak wavelengths at 434.5 nm and 523.5 nm.

### Synthetic Example 7

Synthesis of MTEG 11-aminoundecanoate

11-Aminoundecanoic acid (Kishida Kagaku; 10.0 g), 1M aqueous solution of sodium hydroxide (Kishida Kagaku; 70 mL), 1,4-dioxane (Kokusan Kagaku; 130 mL) and water (70 mL) were mixed in a flask and stirred at room temperature until the content was completely dissolved. The flask was transferred onto a cold water bath, di-tert-butyl dicarbonate (Aldrich; 11.9 g) was added and the mixture was stirred at room temperature for 3 hours and allowed to stand at room temperature for one night. After the reaction mixture was concentrated in vacuo, ethyl acetate (Junsei Kagaku; 150 mL) was added, then citric acid monohydrate (Kanto Kagaku) was added until pH of the solution became 3-4 and the mixture was stirred at room temperature for 5 minutes. An aqueous layer was extracted with ethyl acetate and the extract was combined with an organic layer, washed with water and then with a saturated saline, dried over sodium sulfate, filtered, concentrated and dried in vacuo at room temperature to give 11-(N-tert-butoxycarbonyl)aminoundecanoic acid (1).

11-(N-tert-Butoxycarbonyl)aminoundecanoic acid (6.00 g), triethylene glycol monomethyl ether (hereinafter, abbreviated as MTEG; 3.61 g), 4-dimethylaminopyridine (Tokyo Kasei; 244 mg) and methylene chloride (Junsei Kagaku; 300 mL) were mixed in a flask, 1-ethyl-3-(3′-dimethylaminopropyl)carbodiimide hydrochloride (Tokyo Kasei; 4.20 g) was added at 0° C. with stirring and the mixture was stirred at 0° C. for 2 hours and then at room temperature for 1 hour and allowed to stand at room temperature for one night. Water (100 mL) was added to the reaction mixture followed by stirring at room temperature for 1 hour and the organic layer was washed with water, 10% aqueous solution of citric acid, water, saturated aqueous solution of sodium bicarbonate and water in this order. The mixture was dried over sodium sulfate, filtered and concentrated to give a colorless oily substance. Methylene chloride (5 mL) was added to the flask wherein the oily substance was placed and, after dissolving, it was transferred onto a cold water bath. Trifluoroacetic acid (Kishida Kagaku; 15 mL) was added thereto with stirring followed by stirring at room temperature for 1 hour and methylene chloride and trifluoroacetic acid were evaporated in vacuo at 50° C. at the pressure of 10 mmHg or lower. The reaction solution was added to 1M sodium bicarbonate solution (100 mL), a saturated sodium bicarbonate solution was added thereto until the solution became alkaline and the mixture was extracted with chloroform (Junsei Kagaku). The organic layer was washed with water, dried over sodium sulfate, filtered, concentrated and dried in vacuo at room temperature (4.348 g).

In an IR spectrum, this product gave absorption bands at 1734 cm⁻¹ assigned to ester group, at 3310 cm⁻¹ and 1634 cm⁻¹ assigned to amino group, at 1111 cm⁻¹ assigned to ether structure derived from MTEG and at 2922 cm⁻¹ and 2853 cm⁻¹ assigned to hydrocarbon structure derived from aminoundecanoic acid and MTEG. Further, ¹H-NMR gave rational signal and integral value corresponding to the expected structure as will be mentioned later and, therefore, it was concluded that MTEG 11-aminoundecanoate (hereinafter, abbreviated as MTEG-C11NH₂) of the already-mentioned formula (5) was isolated.

¹H-NMR spectrum: 1.16-1.75 (multiplet, 16 protons, carboxylic acid aliphatic chain), 2.33 (triplet, 2 protons, J=7.6 Hz, methylene group at the side of carbonyl adjacent to ester bond), 2.69 (triplet, 2 protons, J=7.0, methylene group adjacent to amino group), 3.39 (singlet, 3 protons, methyl group), 3.50-3.80 (multiplet, 10 protons), 4.23 (triplet, 2 protons, J=4.86, methylene group at the side of MTEG adjacent to ester bond).

### Example 5

Synthesis of CdSe Nanoparticles Coordinated with MTEG-C11NH₂

Ethanol (Junsei Kagaku K. K.; 8 mL) was added to CdSe-TOPO (0.03 g) obtained by the operation mentioned in Synthetic Example 4 and MTEG-C11NH₂ (0.03 g) synthesized in Synthetic Example 7 followed by heating to reflux with stirring for about 3 hours in an argon atmosphere. As a result of this heating to reflux, the semiconductor nanoparticles of Synthetic Example 4 were dissolved giving a red ethanolic solution without turbidity. To the residue obtained by a vacuum concentration of the reaction solution was added n-hexane, the mixture was irradiated with ultrasonic wave for about 20 seconds to disperse and an insoluble substance was separated by means of centrifugal separation (at 3,000 rpm for 6 minutes) and decantation. The insoluble substance separated as such was dissolved again in a mixed liquid (3 mL) of toluene and chloroform in a 1:1 ratio by volume, the solution was injected into n-hexane (20 mL) and the resulting isolated substance was separated by centrifugal separation and decantation as same as mentioned above. Those operations of re-dissolving, isolation and separation were repeated twice to purify. When toluene (10 mL) was added to the precipitate obtained as such, it was not completely dissolved but resulted in a turbid state. When the solution was applied to a centrifugal separator, an insoluble substance was precipitated. This insoluble substance was presumed to be MTEG-C11NH₂ which was not coordinated to the particles. The supernatant liquid obtained by the decantation was filtered using a membrane filter (0.45 μm), amount of the liquid was decreased to about 3 mL by means of evaporation followed by adding to hexane (20 mL) and the resulting precipitate was recovered by centrifugal separation. This was dried in vacuo at room temperature to remove the solvent whereupon a red solid (26.4 mg) was obtained. The weight loss of the red solid during the TG measurement was 37%.

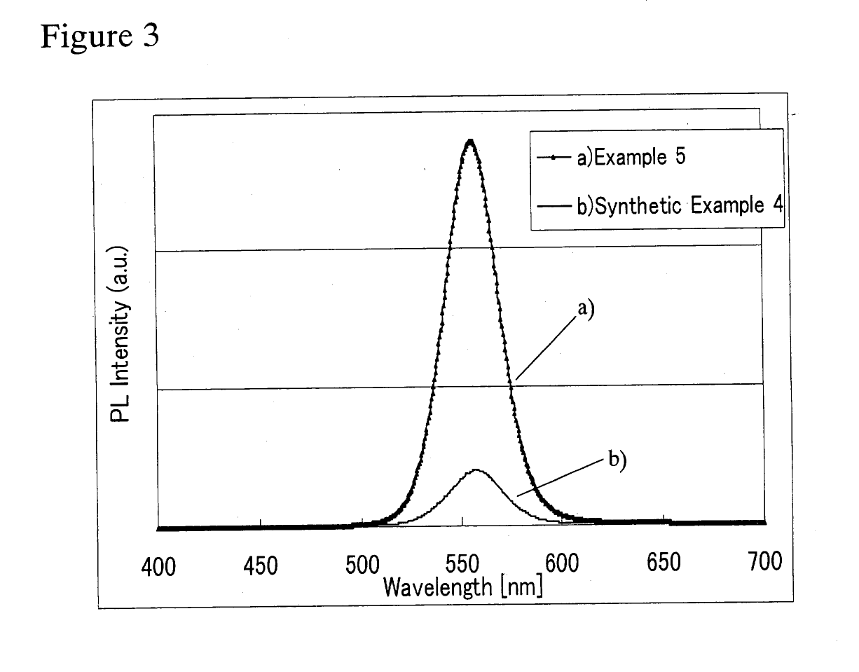

The red solid prepared as such was soluble in toluene, chloroform, ethanol or 25% aqueous solution of ethanol to give a red solution without turbidity. Peak positions of absorption band and luminescent band were unchanged from those of CdSe-TOPO before subjecting to a ligand exchange. When it was compared with CdSe-TOPO having the same absorbance using the same toluene as a solvent, peak emission intensity of luminescent band of CdSe nanoparticles coordinated with MTEG-C11NH₂ was 7-fold (excitation light: 365 nm) (FIG. 3). When a solution of the solid product in a mixed solvent of toluene and chloroform was subjected to a spin coating on a glass substrate, a red coated film without turbidity was resulted and this coated film gave nearly the same luminescent band as in the case of a solution.

### Example 6

Synthesis of CdSe Nanoparticles Having ZnS Shell Coordinated with MTEG-C11NH₂

Ethanol (Junsei Kagaku K. K.; 8 mL) was added to CdSe—ZnS/TOPO (0.03 g) obtained by the operation mentioned in Synthetic Example 5 and MTEG-C11NH₂ (0.03 g) synthesized in Synthetic Example 7 followed by heating to reflux with stirring for about 3 hours in an argon atmosphere. As a result of this heating to reflux, the semiconductor nanoparticles of Synthetic Example 5 were dissolved giving a red ethanolic solution without turbidity. To the residue obtained by a vacuum concentration of the reaction solution was added n-hexane, the mixture was irradiated with ultrasonic wave for about 20 seconds to disperse and an insoluble substance was separated by centrifugal separation (at 3,000 rpm for 6 minutes) and decantation. The insoluble substance separated as such was dissolved again in a mixed liquid (3 mL) of toluene and chloroform in a ratio of 2:1 by volume, the solution was injected into n-hexane (20 mL) and the resulting isolated substance was separated by centrifugal separation and decantation as same as mentioned above. Those operations of re-dissolving, isolation and separation were repeated twice to purify. When toluene (10 mL) was added to the precipitate obtained as such, it was not completely dissolved but resulted in a turbid state. When the solution was applied to a centrifugal separator, an insoluble substance was precipitated. This insoluble substance was presumed to be MTEG-C11NH₂ which was not coordinated to the particles. The supernatant liquid obtained by the decantation was filtered using a membrane filter (0.45 μm), amount of the liquid was decreased to about 3 mL by means of evaporation followed by adding to hexane (20 mL) and the resulting precipitate was recovered by centrifugal separation. This was dried in vacuo at room temperature to remove the solvent whereupon a red solid (34.7 mg) was obtained.

The red solid prepared as such was soluble in toluene, chloroform or ethanol to give a red solution without turbidity. Peak positions of absorption band and luminescent band were unchanged from those of CdSe/ZnS-TOPO before subjecting to a ligand exchange.

When a solution of the solid product in a mixed solvent of toluene and chloroform was subjected to a spin coating on a glass substrate, a red coated film without turbidity was resulted and this coated film gave nearly the same luminescent band as in the case of a solution.

### Example 7

Synthesis of CdS Nanoparticles Coordinated with MTEG-C11NH₂

Ethanol (Junsei Kagaku K. K.; 5 mL) was added to CdS-TOPO (0.03 g) obtained by the operation mentioned in Synthetic Example 6 and MTEG-C11NH₂ (0.09 g) synthesized in Synthetic Example 7 followed by heating to reflux with stirring for about 3 hours in an argon atmosphere. As a result of this heating to reflux, the semiconductor nanoparticles of Synthetic Example 6 were dissolved giving a yellow ethanolic solution without turbidity. To the residue obtained by a vacuum concentration of the reaction solution was added n-hexane, the mixture was irradiated with ultrasonic wave for about 20 seconds to disperse and an insoluble substance was separated by centrifugal separation (at 3,000 rpm for 6 minutes) and decantation. The insoluble substance separated as such was dissolved again in a mixed liquid (3 mL) of toluene and chloroform in a ratio of 2:1 by volume, the solution was injected into n-hexane (20 mL) and the resulting isolated substance was separated by centrifugal separation and decantation as same as mentioned above. Those operations of re-dissolving, isolation and separation were repeated twice to purify. When toluene (10 mL) was added to the precipitate obtained as such, it was not completely dissolved but resulted in a turbid state. When the solution was applied to a centrifuge, an insoluble substance was precipitated. This insoluble substance was presumed to be MTEG-C11NH₂ which was not coordinated to the particles. The supernatant liquid obtained by the decantation was filtered using a membrane filter (0.45 μm), amount of the liquid was decreased to about 3 mL by means of evaporation followed by adding to hexane (20 mL) and the resulting precipitate was recovered by centrifugal separation. This was dried in vacuo at room temperature to remove the solvent whereupon a yellow solid (13.6 mg) was obtained. The weight loss of the yellow solid during the TG measurement was 36%.

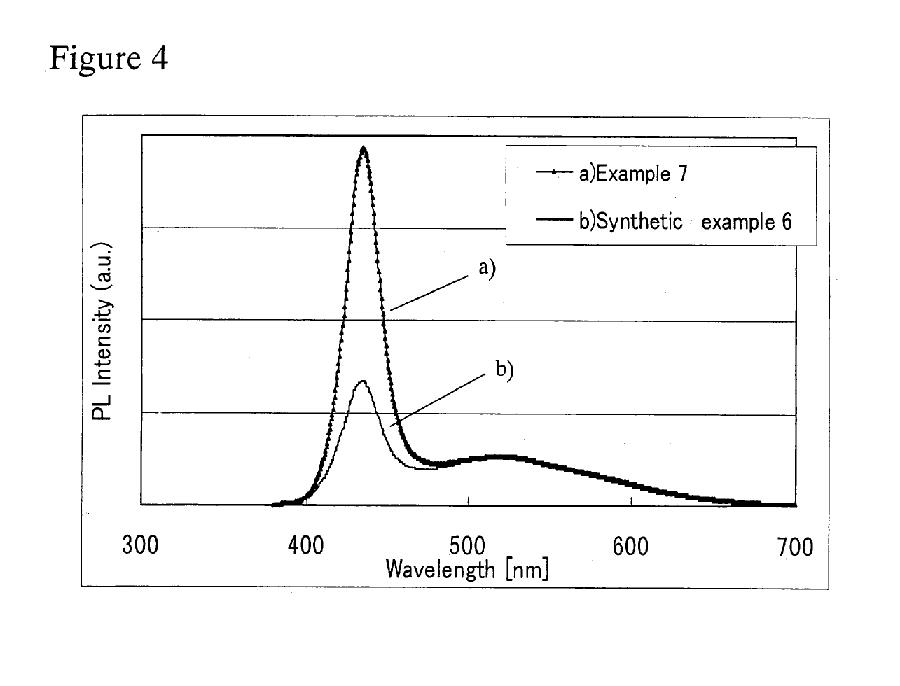

In the IR spectrum of the yellow solid prepared as such, an absorption peak assigned to ester group (1736 cm⁻¹) derived from MTEG-C11NH₂ was confirmed and, therefore, it was presumed that MTEG-C11NH₂ was coordinated. When this solid was dispersed in toluene, chloroform, ethanol or 25% aqueous solution of ethanol, there was obtained a yellow solution without turbidity. Peak position of absorption band was 412 nm while peak positions of luminescent band were 435 nm and 521 nm (excitation light: 366 nm). When they were compared with CdS-TOPO having the same absorbance using the same toluene as a solvent, it was observed that, in the two luminescent bands in CdS nanoparticles coordinated with MTEG-C11NH₂, the peak emission intensity at the shorter wavelength was 2.9-fold while that at the longer wavelength was almost unchanged (FIG. 4). Here, it was presumed that the luminescent band at the shorter wavelength and that at the longer wavelength were emissions derived from exciton emission and surface level or the like, respectively and, as a result of coordination of MTEG-C11NH₂, intensity of only exciton was able to be enhanced. When a solution of the solid product in toluene was subjected to a spin coating on a glass substrate, a yellow coated film without turbidity was resulted and this coated film gave nearly the same luminescent band as in the case of a solution.

### Synthetic Example 8

Synthesis of CdSe Nanocrystals

TOPO (Aldrich; 4 g) was placed in a three-necked flask made of colorless and transparent Pyrex glass equipped with an air-cooling Liebig condenser and a thermocouple for adjusting the reaction temperature and heated at 360° C. in a dry argon gas atmosphere with stirring by a magnetic stirrer. On the other hand, a material solution where dimethyl cadmium (Strem Chemical; 97%; 0.216 g) was mixed with and dissolved in a liquid where selenium (black power of a single substance; 0.1 g) was dissolved in TBP (6.014 g) in a glove box of a dry nitrogen atmosphere was prepared in a light-shield glass bottle which was sealed by a rubber stopper (Septum supplied from Aldrich) and packed with aluminum foil without any aperture. A part (2.0 mL) of this material solution was subjected to a single continuous injection using an injector into the above flask in which TOPO was charged and that stage was defined as the starting time for the reaction. After 20 minutes from the start of the reaction, the heat source was removed and, when the mixture was cooled down to about 50° C., pure toluene (2 mL) was added by an injector to dilute and then the above pure methanol (10 mL) was injected to prepare an insoluble substance. The insoluble substance was centrifuged (at 3,000 rpm), separated therefrom by removing the supernatant liquid by means of decantation and dried in vacuo at room temperature for about 14 hours to give solid powder.

In an XRD spectrum of this solid powder, diffractive peaks assigned to face 002 and face 110 of CdSe crystal of a Wurtzite type were observed and, therefore, production of CdSe nanocrystals was confirmed. Average particle size of the CdSe nanocrystals was about 4 nm according to an observation under a TEM. The CdSe nanocrystals gave a red luminescent band (peak wavelength: 595 nm; half band width: 43 nm) when irradiated with excitation light of 366 nm wavelength in a pure toluene solution.

### Synthetic Example 9

Synthesis of CdSe Nanocrystals Having ZnS Shell

This was carried out according to a method mentioned in B. O. Dabbousi, et al.: J. Phys. Chem. B, volume 101, page 9463 (1997). That will be illustrated as hereunder.

TOPO (15 g) was placed in a three-necked flask made of brown glass equipped with an air-cooling Liebig condenser and a thermocouple for adjusting the reaction temperature in a dry argon atmosphere and stirred for about 2 hours in vacuo in a fused state of 130-150° C. During that period, operations of recovering to atmospheric pressure by dry argon gas were repeated for several times with an object of substituting the residual volatile matters such as air and water. The temperature was set at 100° C. and, after about 1 hour, a solution of solid powder of CdSe nanocrystals (0.094 g) prepared in Synthetic Example 8 in trioctyl phosphine (1.5 g; hereinafter abbreviated as TOP) was added to give a transparent solution containing CdSe nanocrystals. This was stirred at 100° C. in vacuo for about 80 minutes more, the temperature was set at 180° C. and the pressure was recovered to atmospheric pressure with dry argon gas. On the other hand, a material solution by dissolving a 1N n-hexane solution of diethyl zinc (Aldrich; 1.34 mL; 1.34 mmol) and bis(trimethylsilyl) sulfide (0.239 mL; 1.34 mmol) in trioctyl phosphine (hereinafter, abbreviated as TOP; 9 mL) in a glove box of a dry nitrogen atmosphere was prepared in a glass bottle shielded from light by sealing with Septum and wrapped with aluminum foil without any aperture. The material solution was dropped by an injector into the above transparent solution of 180° C. containing the CdSe nanocrystals during 20 minutes, temperature was lowered to 90° C. and stirring was continued for about 1 hour. After it was allowed to stand at room temperature for about 14 hours, it was heated again with stirring at 90° C. for 3 hours. The heat source was removed, n-butanol (8 mL) of an anhydrous grade (99.8%) supplied from Aldrich was added to the reaction solution and the mixture was cooled down to room temperature to give a transparent red solution.

This red solution had no smell of sulfur compounds such as bis(trimethylsilyl) sulfide which is a material but had a leek-like smell specific to selenium. A solution of CdSe nanocrystals prepared in Synthetic Example 8 had no such a selenium sell and, therefore, it was presumed that, together with the progress of the intended reaction for the production of a sulfide on the surface of the said CdSe nanocrystals, liberation of selenium took place by some mechanism such as substitution reaction of selenium atom by sulfur atom on the surface of the said nanocrystals and it was presumed that, as same as in the description of the above-mentioned literature, CdSe nanocrystals having ZnS shell was produced.

As a result of a precipitating operation where a part (8 mL) of the red solution was dropped into pure methanol (16 mL) at room temperature in a dry nitrogen atmosphere and stirring was continued for 20 minutes, a red insoluble substance was obtained. This red insoluble substance was separated by means of centrifugal separation and decantation by the same manner as in Synthetic Example 8 and dissolved in pure toluene (14 mL) again. The resulting re-dissolved toluene solution was again subjected to the same series of purifying operations including precipitation, centrifugal separation and decantation to give a solid product. The solid product was washed by shaking with 1 mL of pure methanol and separated by decantation. The solid product gave a transparent red solution in pure toluene and, when excitation light of 468 nm wavelength was irradiated thereto, it gave a red luminescent band (peak wavelength: 597 nm; half band width: 41 nm). Since this emission showed clearly bigger emission intensity in the solution concentration of the same degree than the case of the CdSe nanoparticles prepared in Synthetic Example 8, it was presumed that conversion to CdSe nanocrystals having ZnS shell took place and that contribution of non-emission process via surface level was suppressed. In addition, an IR spectrum of this product gave three absorption bands presumably derived from alkyl group of TOPO at 2940, 2920 and 2850 cm⁻¹ and, therefore, it was presumed that TOPO was bonded on the surface of the nanocrystals.

### Synthetic Example 10

Synthesis of ZnO Nanocrystals

The synthesis was carried out according to a method mentioned in the above-mentioned literature by L. Spanhel, et al. Thus, zinc acetate dehydrate (0.8789 g) supplied from Kanto Kagaku K. K. was dissolved in ethanol (40 mL) in a glass flask shielded from light, bubbling with nitrogen gas was carried out for 30 minutes to substitute the air dissolved therein and the solution was heated in a nitrogen atmosphere whereby a part (24 mL) of ethanol was distilled and the co-existing water was azeotropically removed. Temperature of the liquid was returned to room temperature, ethanol (24 mL) was added, then powder of lithium hydroxide monohydrate (0.2352 g) supplied from Kishida Kagaku K. K. was added thereto and the mixture was subjected to an ultrasonic wave irradiation for 10 minutes to give a solution without turbidity. Since the absorption spectrum of this solution showed an exciton luminescent band having a maximum at 314 nm, it was noted that, as mentioned in the above-mentioned literature, ZnO nanocrystals were produced. The solution also gave a broad luminescent band having a peak at 496 nm by excitation light of 300 nm.

### Example 8

Synthesis of MTEG 3-mercaptopropanoate

3-Mercaptopropanoic acid (4.32 g) supplied from Tokyo Kasei, triethylene glycol monomethyl ether (hereinafter, abbreviated as MTEG; 104.16 g) and concentrated sulfuric acid (0.63 g) were mixed in a flask in a dry nitrogen atmosphere and, together with stirring at 60° C., vacuation at the pressure of 10 mmHg or lower was continued for 10 hours. To the reaction solution was added anhydrous potassium carbonate (Kanto Kagaku) which was in the same equivalent as concentrated sulfuric acid, MTEG was distilled by means of a vacuum distillation (steam temperature of 100-103° C. at the pressure of 1.5 mmHg) to concentrate and the residue was purified by means of a silica gel column chromatography (being eluted with n-hexane/acetone=75/25-60/40). In an IR spectrum, the resulting product gave absorption bands assigned to an ester group at 1730 cm⁻¹ and assigned to a hydrocarbon structure moiety of MTEG at a broad region of 3050-2650 cm⁻¹ including a peak of 2870 cm⁻¹ and a shoulder of 2820 cm⁻¹. Further, ¹H-NMR gave rational signal and integral value corresponding to the expected structure as will be mentioned later and, therefore, it was concluded that the aimed MTEG ester of 3-mercaptopropanoic acid (hereinafter, abbreviated as MTEG-C3SH) was isolated.

¹H-NMR spectrum: 2.64 (triplet, 2 protons, J=7.3 Hz, methylene group derived from the material carboxylic acid residue), 2.81 (triplet, 2 protons, J=6.9 Hz, methylene group derived from the material carboxylic acid residue), 3.38 (singlet, 3 protons, methyl group), 3.53-3.58 (multiplet, 2 protons), 3.63-3.73 (multiplet, 8 protons), 4.26 (triplet, 2 protons, J=5.0 Hz, methylene group the MTEG residue adjacent to ester bond).

### Example 9

Synthesis of Semiconductor Nanoparticles Bonded with MTEG-C3SH

All of the CdSe nanocrystals having ZnS shell prepared in Synthetic Example 9 were dissolved in pure toluene (2 mL) in a dry nitrogen atmosphere in a glass container which was shielded from light by wrapping with aluminum foil without any aperture and made into a homogeneous solution by further addition of pure methylene chloride (10 mL). To this was added a solution of MTEG-C3SH (0.29 g) synthesized in Example 8 in pure methylene chloride (2 mL) with stirring, then stirring under the condition of shielding from light at room temperature was continued for about 2 hours and the mixture was allowed to stand at room temperature for about 17 hours. After that, pure toluene (6 mL) was added thereto, temperature was raised to 100° C. in a dry nitrogen stream to evaporate methylene chloride and, at the same time, heating was conducted for 45 minutes followed by cooling down to room temperature. To this reaction solution was added n-hexane (Junsei Kagaku K. K.) in about 9-fold by volume and the resulting insoluble substance was subjected to a purifying operation by means of centrifugal separation and decantation by the same manner as in the above-mentioned Synthetic Example 8. The insoluble substance separated as such was dissolved in pure toluene (1 mL) again and the same purifying operation (addition of n-hexane in about 9-fold by volume followed by subjecting to centrifugal separation and decantation) was repeated to give a solid product. Since organic impurities TOPO or an excessive MTEG-C3SH, etc. were soluble or dispersible in a mixed solvent of toluene/n-hexane (1:9 by volume), they were removed by the purifying operation mentioned here.

The solid product prepared as such had both solubility in a 50% by weight aqueous solution of ethanol and luminescent ability (peak wavelength of luminescent band by excitation wavelength of 468 nm was 602 nm while half band width was 39 nm). The IR spectrum of the solid product prepared as such gave absorption bands assigned to an ester group derived from the used MTEG-C3SH (1730 cm⁻¹) and to a hydrocarbon structure moiety (a broad range of 3000-2750 cm⁻¹ including a peak at 2870 cm⁻¹ and a shoulder at 2820 cm⁻¹) and, further, the three sharp absorption peaks presumed to be derived from alkyl group of TOPO mentioned in the above Synthetic Example 9 were not observed. Accordingly, it was presumed that semiconductor nanoparticles where MTEG-C3SH was substituted for TOPO and was coordinated therewith.

### Example 10

Synthesis of MTEG 11-mercaptoundecanoate

11-Mercaptoundecanoic acid (1.70 g), MTEG (50 mL) used in Example 8 and concentrated sulfuric acid (Kokusan Kagaku K. K.; 5 drops) were mixed in a flask of a dry nitrogen atmosphere and, together with stirring at 60° C., dehydration in vacuo at the pressure of 30 mmHg or lower was carried out for about 36 hours in total. The isolated substance which was obtained by a gradual addition of the reaction solution to a large amount of ice water with stirring was extracted with a mixed solvent of n-hexane/ethyl acetate (both Junsen Kagaku K. K.) and the organic phase was washed with a saturated aqueous solution of sodium bicarbonate and then with water, dried over sodium sulfate, filtered, concentrated and dried in vacuo at room temperature. Density of the product at 23° C. was 1.009. The IR spectrum of the product gave absorption bands assigned to an ester group at 1735 cm⁻¹ and to a hydrocarbon structure derived from MTEG including peaks of 2920 cm⁻¹ and 2845 cm⁻¹. Further, ¹H-NMR spectrum gave rational signal and integral value corresponding to the expected structure as will be mentioned later. Accordingly, it was concluded that MTEG ester of 11-mercaptopropanoic acid of the already-mentioned formula (5) (hereinafter, abbreviated as MTEG-C11SH) was isolated. ¹H-NMR spectrum: 1.25-1.67 (multiplet, 18 protons, aliphatic chain), 2.33 (triplet, 2 protons, J=7.6 Hz, methylene group derived from the material carboxylic acid residue), 3.38 (singlet, 3 protons, methyl group), 3.54-3.58 (multiplet, 2 protons), 3.63-3.72 (multiplet, 8 protons), 4.23 (triplet, 2 protons, J=5.0 Hz, methylene group of MTEG residue adjacent to ester bond).

### Example 11

Synthesis of Semiconductor Nanoparticles Bonded with MTEG-C11SH (No. 1)

CdSe nanocrystals having ZnS shell (0.5 g) prepared by the same operations mentioned in Synthetic Example 8 and Synthetic Example 9 was dispersed in ethanol (Junsei Kagaku K. K.; 8 mL) with stirring in a nitrogen atmosphere and, at the same time, MTEG-C11SH (0.4 g) synthesized in Example 10 was added thereto followed by heating to reflux for about 20 minutes. The heating to reflux gave a red ethanolic solution without turbidity wherein the semiconductor nanocrystals of Synthetic Example 9 were dissolved. To the residue obtained by a vacuum concentration of the reaction solution was added n-hexane used in Example 9, the mixture was irradiated with ultrasonic wave for about 20 seconds to disperse and then an insoluble substance was separated by means of centrifugal separation (at 4,000 rpm for 6 minutes) and decantation. The insoluble substance separated as such was dissolved in pure toluene again, injected into n-hexane of about 10-fold by volume and the isolated substance produced thereby was separated by means of centrifugal separation and decantation by the same manner as above. The operation of re-dissolving, isolation and separation was repeated once again to purify. When the solid obtained by drying in vacuo at room temperature was dissolved in ethanol or in a 50% aqueous solution of ethanol, a red solution without turbidity was obtained. The said ethanolic solution gave the same emission bands as in the case of Example 9. The IR spectrum of this solid product gave absorption bands assigned to a hydrocarbon structure moiety and an ester group derived from the used MTEG-C11SH and, further, the three sharp absorption peaks supposed to be derived from alkyl group of TOPO mentioned in the above Synthetic Example 9 were not observed. Accordingly, it was presumed that there were obtained semiconductor nanoparticles where MTEG-C11SH was substituted for TOPO and coordinated therewith. When the content of the organic substance was measured by the above TG, it was found to be 29% by weight. When an ethanolic solution of this solid product was subjected to a spin coating on a glass substrate, a red coated film without turbidity was obtained and the coated film showed the same luminescent ability as above.

### Example 12

Synthesis of Semiconductor Nanoparticles Bonded with MTEG-C11SH (No. 2)

About 15% by volume of the solution containing ZnO nanocrystals obtained in Synthetic Example 10 were collected, MTEG-C11SH (0.2000 g) synthesized in Example 10 was added thereto and the mixture was heated to reflux at 70° C. for 2 hours with stirring in a nitrogen atmosphere. After that, it was purified by means of dialysis using ethanol using a permeable membrane UC36-32-100 made of cellulose supplied from Sanko Junyaku K. K. (manufactured by Viskase Sales Corp.; upper limit of permeating molecular weight described in the catalog: 12,000-14,000) whereby low-molecular substances such as salts and an excessive amount of MTEG-C11SH were removed. The residue obtained by concentration of the purified ethanolic solution in vacuo was able to be dissolved in ethanol again giving a solution without turbidity and still had the exciton absorption bands of Synthetic Example 10. From the comparison with Comparative Example 3 which will be mentioned later, it was presumed that the product of the present Example was ZnO where MTEG-C11SH was bonded on the surface and that, as a result of such an effect, changes in exciton absorption bands as a result of growth of nanocrystals were suppressed and further that the property of re-dissolving in ethanol was achieved.

### Synthetic Example 11

Synthesis of InP Nanocrystals Having ZnS Shell

This was carried out according to a method mentioned in O. I. Micic, et al.: J. Phys. Chem. B, volume 102, page 9791. That will be illustrated as hereunder.

Trioctylphosphine (Aldrich; 6 g; hereinafter, abbreviated as TOP) was placed in a three-necked flask made of colorless and transparent Pyrex® glass equipped with an air-cooling Liebig condenser and a thermocouple for adjusting the reaction temperature and heated at 300° C. in a dry argon atmosphere together with stirring using a magnetic stirrer. On the other hand, a material solution where a solution (prepared by heating a dry argon atmosphere at 260° C. for 10 hours; 1 mL) in which indium chloride (manufactured by Kishida Kagaku; 3 g) was dissolved in TOP (10 mL) and a liquid in which tristrimethylsilyl phosphine (manufactured by Across; 0.2832 g) was dissolved in TOP (1 mL) were mixed in a glove box was prepared in a glass bottle shielded from light by sealing with rubber stopper. All of the material solution was subjected to a single continuous injection by an injector into the above flask containing TOP and that stage was defined as the starting time of the reaction. Immediately after the injection, the temperature was set at 260° C. and heating was continued for 9 hours. After that, it was allowed to cool to room temperature, allowed to stand for one night, heated at 260° C. again for 9 hours, allowed to cool, then allowed to stand for one night and heated for 6 hours more. After that, the heat source was removed and, when the solution was cooled down to about 60° C., anhydrous n-butanol (20 mL) was added to the reaction solution and the mixture was cooled down to room temperature. The reaction solution was dropped into anhydrous methanol (100 mL) and stirred for 5 minutes to give a black insoluble substance. The insoluble substance was centrifuged (3,000 rpm) and the supernatant liquid was removed and separated by decantation to give solid powder. The solid powder was dissolved in toluene (25 mL) and filtered through a membrane filter having a pore size of 0.2 μm, the solution was concentrated to 15 mL by an N₂ flow and dropped into a mixed solvent of anhydrous methanol/anhydrous n-butanol (50 mL/25 mL) and the insoluble substance was centrifuged by the same manner as above. When the insoluble substance was dried in vacuo for one night to give a black solid (hereinafter, abbreviated as InP-TOP; 158.8 mg). The black solid prepared as such was dissolved in chloroform and its absorption spectrum was measured to give the same absorption spectrum as described in the above-mentioned literature. When an emission spectrum was measured (excitation light: 450 nm), emission was rarely noted.

TOPO (3 g), TOP (5 mL) and InP nanocrystals (0.030 g) prepared hereinabove were stirred for about 1 hour in vacuo at 100° C. in a three-necked flask made of brown glass equipped with an air-cooling Liebig condenser and a thermocouple for adjusting the reaction temperature and, after that, the temperature was set at 260° C. followed by returning to atmospheric pressure using argon. On the other hand, a material solution by dissolving a 1N n-hexane solution (0.8 mL) of diethyl zinc and bis(trimethylsiyl) sulfide (0.1687 mL) in TOP (5 mL) in a glove box of a dry nitrogen atmosphere was prepared in a glass bottle sealed by a rubber stopper. All of the material solution was dropped using an injector into the above transparent solution of 260° C. containing the InP nanocrystals during 45 minutes, temperature was lowered to 100° C. and, after that, stirring was continued for about 4 hours more. After it was allowed to stand at room temperature for one night, toluene (20 mL) was added thereto, the reaction solution was transferred to a colorless and transparent glass bottle and an insoluble substance was precipitated by centrifugal separation followed by being allowed to stand as it was for five days. The reaction solution was dropped into anhydrous methanol (80 mL) and stirred for 5 minutes to give a black insoluble substance. The black insoluble substance was separated by means of centrifugal separation and decantation as same as before, dissolved in toluene (10 mL), filtered through a membrane filter having a pore size of 0.2 μm, concentrated to 7 mL by an N₂ flow and dropped into a mixed solvent of anhydrous methanol/anhydrous n-butanol (40 mL/20 mL). The insoluble substance was separated by means of centrifugal separation and decantation as same as above and dried in vacuo for one night to give a black solid (hereinafter, abbreviated as InP/ZnS-TOPO; 63.1 mg). The black solid prepared as such was dissolved and its absorption spectrum was measured whereupon the same absorption spectrum as in the case of the above InP-TOP was noted. When an emission spectrum was measured (excitation light: 450 nm), a red luminescent band (peak wavelength: 625 nm) was noted. In nearly the same solution concentration, the InP nanocrystals before having ZnS shell hardly showed luminescence and, therefore, it was presumed that conversion to InP nanocrystals having ZnS shell took place and that contribution of non-luminescence process via surface level was suppressed.

### Example 13

Synthesis of InP Nanoparticles Having ZnS Shell Coordinated with MTEG-C10PA

Ethanol (5 mL) was added to InP/ZnS-TOPO (0.020 g) obtained by the operation mentioned in Synthetic Example 11 and MTEG-C10PA (0.020 g) synthesized in Example 1 followed by heating to reflux with stirring for about 6 hours in an argon atmosphere. As a result of this heating to reflux, the semiconductor nanoparticles of Synthetic Example 11 were dissolved giving a black ethanolic solution without turbidity. The residue obtained by a vacuum concentration of the reaction solution was dissolved in toluene (3 mL), the solution was added to n-hexane (25 mL) and an insoluble substance was separated by means of centrifugal separation and decantation. The insoluble substance separated as such was dissolved again in toluene (3 mL), the solution was injected into n-hexane (25 mL) and the resulting isolated substance was separated by means of centrifugal separation and decantation as same as mentioned above. Those operations of re-dissolving, isolation and separation were repeated once again to purify. The precipitate obtained as such was dissolved in toluene (6 mL), filtered through a membrane filter having a pore size of 0.2 μm, concentrated to 3 mL by a N₂ flow and dropped into n-hexane (25 mL). The insoluble substance was separated by means of centrifugal separation and decantation as same as before and dried in vacuo to give a black solid (hereinafter, abbreviated as InP/ZnS-MTEG-C10PA; 21.9 mg).

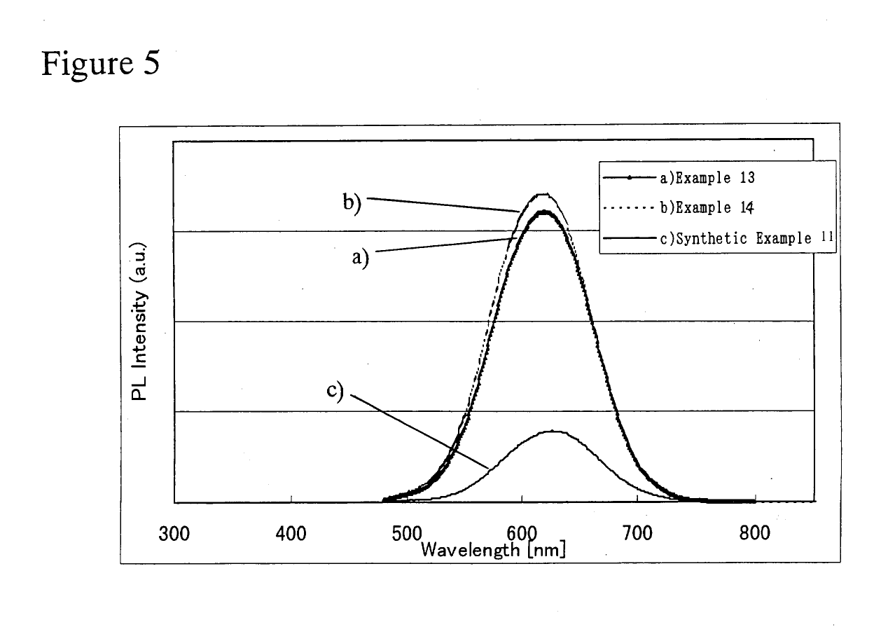

The black solid prepared as such was soluble in toluene, chloroform or ethanol to give a black solution without turbidity. This will be due to coordination of MTEG-C10PA on the surface of InP/ZnS crystals. Peak positions of absorption band and luminescent band were almost unchanged from those of InP/ZnS-TOPO before subjecting to a ligand exchange. When it was compared with InP/ZnS-TOPO having the same absorbance where the same chloroform was used as a solvent, peak emission intensity of luminescent band of InP/ZnS nanoparticles coordinated with MTEG-C10PA increased to 4.1-fold (excitation light: 450 nm) (FIG. 5).

When this black solid (1 mg) was dissolved in a mixed liquid of toluene and chloroform (1:1 by volume; 20 μL) and subjected to a spin coating (500 rpm) on a quartz substrate, a brown coated film without turbidity (thickness: 400 nm) was resulted and this coated film gave a red luminescent band as same as in the case of a solution.

### Synthetic Example 12

Synthesis of 2,5,8-Trioxadecyl-10-phosphonic acid (2-(2-(2-methoxyethoxy) ethoxy) ethyl phosphonic acid)

Triethylene glycol monomethyl ether (hereinafter, abbreviated as MTEG; Tokyo Kasei K. K.; 2.952 g) and triphenylphosphine (Kishida Kagaku K. K.; 7.581 g) were placed in a flask, the inner area of the container was substituted with argon and the content was completely dissolved by adding dry tetrahydrofuran (hereinafter, abbreviated as THF; 50 mL) thereto in an argon stream. The flask was transferred onto an ice bath, carbon tetrabromide (Tokyo Kasei K. K.; 4.951 g) was added thereto little by little during 15 minutes with stirring in an argon stream and the mixture was stirred at room temperature for 3 hours. The reaction mixture was concentrated in vacuo and the resulting concentrated liquid was filtered in vacuo. The solid remaining on the filter paper was washed with n-hexane (Junsei Kagaku K. K.; 50 mL) twice and the filtrate was combined with the washings followed by concentrating in vacuo to give a crude product. The crude product was purified by a silica gel chromatography of an n-hexane-ethyl acetate type to give 2,5,8-trioxa-10-bromodecane.

2,5,8-Trioxa-10-bromodecane (1.602 g) was placed in a flask, the inner area of the container was substituted with argon, tris(trimethylsilyl) phosphite (Tokyo Kasei K. K.; 7.24 g) was added thereto in an argon stream followed by mixing, the mixture was stirred at 120° C. for 18 hours and cooled down to 85° C. with stirring, an excessive tris(trimethylsilyl) phosphite was removed in vacuo and, when no reduction in the amount of the reaction mixture was noted, it was cooled down to room temperature. The inner area of the container was returned to atmospheric pressure with argon, THF/water (in a ratio of 100/1 by volume; 20.2 mL) was added thereto and the mixture was stirred at room temperature for 3 hours. The reaction mixture was concentrated in vacuo, the residue was dissolved in ethanol and the solution was concentrated again in vacuo. The residue was dissolved in chloroform, the resulting solution was passed through a column of silica gel (amount of silica gel: 0.40 g) and the column was washed with chloroform. The solution which passed through the column was combined with the washing and the mixture was concentrated in vacuo and dried at room temperature in vacuo (1.578 g).

In the IR spectrum, the product gave absorption bands assigned to a phosphonic acid structure at 2750 cm⁻¹, 2364 cm⁻¹, 1196 cm⁻¹ and 1016 cm⁻¹, to an ether structure derived from MTEG at 1105 cm⁻¹ and to a hydrocarbon structure derived from MTEG at 2924 cm⁻¹ and 2883 cm⁻¹. Further, ¹H-NMR gave rational signal and integral value corresponding to the expected structure as will be mentioned later. According, it was concluded that ethanol was added to dissolve whereupon 2,5,8-trioxadecyl-10-phosphonic acid (hereinafter, abbreviated as MTEG-C0PA) was isolated.

¹H-NMR Spectrum: 2.14 (doublet-triplet, 2 protons, J=18.1 He, 7.0 Hz, methylene group at the side of phosphonic acid adjacent to ether bond), 3.39 (singlet, 3 protons, methyl group), 3.55-3.65 (multiplet, 8 protons), 3.78 (doublet-triplet, 2 protons, J=14.3 Hz, 7.0 Hz, methylene group at the ether-bonded side adjacent to ether bond), 8.18 (broad singlet, 2 protons, hydroxyl group derived from phosphonic acid)

### Example 14

Synthesis of InP Nanoparticles Having ZnS Shell Coordinated with MTEG-C0PA

Ethanol (3.5 mL) was added to InP/ZnS-TOPO (0.0103 g) obtained by the operation mentioned in Synthetic Example 11 and MTEG-C0PA (0.0126 g) synthesized in Synthetic Example 12 followed by heating to reflux with stirring for about 2.5 hours in an argon atmosphere. As a result of this heating to reflux, the semiconductor nanoparticles of Synthetic Example 11 were dissolved giving a black ethanolic solution without turbidity. The residue obtained by a vacuum concentration of the reaction solution was dissolved in toluene (3 mL), the solution was added to n-hexane (25 mL) and an insoluble substance was separated by means of centrifugal separation and decantation. The insoluble substance separated as such was dissolved again in toluene (25 mL), the solution was injected into n-hexane (25 mL) and the resulting isolated substance was separated by means of centrifugal separation and decantation as same as mentioned above. The precipitate obtained as such was dissolved in toluene (4 mL), filtered through a membrane filter having a pore size of 0.2 μm, concentrated to 2 mL by an N₂ flow and dropped into n-hexane (25 mL). The insoluble substance was separated by means of centrifugal separation and decantation as same as before and dried in vacuo to give a black solid (hereinafter, abbreviated as InP/ZnS-MTEG-C0PA; 6.0 mg).

The black solid prepared as such was soluble in toluene, chloroform or ethanol to give a black solution without turbidity. This will be due to coordination of MTEG-C0PA on the surface of InP/ZnS crystals. Peak positions of absorption band and luminescent band were almost unchanged from those of InP/ZnS-TOPO before subjecting to a ligand exchange. When it was compared with InP/ZnS-TOPO having the same absorbance where the same chloroform was used as a solvent, peak emission intensity of luminescent band of InP/ZnS nanoparticles coordinated with MTEG-C0PA increased to 4.3-fold (excitation light: 450 nm) (FIG. 5).

When this black solid (1 mg) was dissolved in a mixed liquid of toluene and chloroform (1: by volume; 20 μL) and subjected to a spin coating (500 rpm) on a quartz substrate, a brown coated film without turbidity (thickness: 250 nm) was resulted and this coated film gave a red luminescent band as same as in the case of a solution.

### Synthetic Example 13

Synthesis of MTEG 11-mercaptoundecanoate

11-Mercaptoundecanoic acid (1.70 g), triethylene glycol monomethyl ether supplied from Tokyo Kasei K. K. (hereinafter, abbreviated as MTEG; 50 mL) and concentrated sulfuric acid (Kokusan Kagaku K. K.; 5 drops) were mixed in a flask in a dry nitrogen atmosphere and, together with stirring at 60° C., dehydration in vacuo under the pressure of 30 mmHg or lower was carried out for about 36 hours in total. The reaction solution was gradually added to a large amount of ice water with stirring, the resulting isolated substance was extracted with a mixed solvent of n-hexane/ethyl acetate (in a ratio of 5/1 by volume; both Junsei Kagaku K. K.) and this organic phase was washed with a saturated aqueous solution of sodium bicarbonate and then with water, dried over sodium sulfate, filtered, concentrated and dried in vacuo at room temperature. Density of the product was 1.009 at 23° C. In IR spectrum, this product gave absorption bands assigned to an ester group at 1730 cm⁻¹ and to a hydrocarbon structure derived from TEGMME in a broad region of 3050-2650 cm⁻¹ including a peak at 2870 cm⁻¹ and a shoulder at 2820 cm⁻¹. Therefore, production of MTEG ester of 11-mercaptoundecanoic acid (hereinafter, abbreviated as HS-MTEG) having a structure of the already-mentioned formula (4) was confirmed.

### Synthetic Example 14

Synthesis of CdS Crystal Particles

In a glove box of a dry nitrogen atmosphere, tributylphosphine (hereinafter, abbreviated as TBP; 5.625 g), a 10% by weight solution of dimethyl cadmium in n-hexane (1.40 g) and bis(trimethylsilyl) sulfide (0.0825 mL) are mixed in a glass bottle and sealed with a rubber stopper (Septum supplied from Aldrich) (as hereinafter, the mixed liquid will be referred to “material solution A”). Apart from the material solution A, surface of a colorless and transparent three-necked flask (inner volume: 100 mL) used as a reactor made of Pyrex (registered trade mark) glass equipped with an air-cooling Liebig condenser and a thermocouple for adjusting the reaction temperature are covered with aluminum foil, trioctylphosphine oxide (hereinafter, abbreviated as TOPO; 12 g) is placed therein and, together with stirring using a magnetic stirrer, drying in vacuo is conducted at 150° C. for 3 hours. During that period, an operation of substituting the inner atmosphere where the inner volume is returned to atmospheric pressure with dry argon gas and then evacuated is carried out for three times. After that, temperature is raised to 300° C. and the same substitution operation for the inner atmosphere is carried out for three times. Finally, the inner volumne is made into an argon gas atmosphere, heating is continued for 30 minutes, the above-mentioned material solution A is subjected to a single continuous injection using an injector thereinto and that time is defined as the starting time of the reaction. After 20 minutes from the start of the reaction, the heat source is removed and, when cooled down to 50° C., anhydrous methanol (1.2 mL) is added to dilute followed by being allowed to cool down to room temperature. The reaction solution is injected into anhydrous methanol (45 mL) in a dry nitrogen atmosphere and stirred at room temperature for 5 minutes to give an insoluble substance. The insoluble substance is subjected to centrifugation (3,000 rpm) and decantation to remove the supernatant liquid to give a yellow solid. The solid is dissolved in pure toluene (2 mL), injected into anhydrous methanol (30 mL), stirred at room temperature for 15 minutes and subjected to the same centrifugal separation and decantation as before to separate a yellow solid precipitate. The solid is dried at room temperature in a dry nitrogen stream and dried in vacuo at room temperature for one night to give yellow solid powder (84.8 mg). The yellow solid powder prepared as such is soluble in toluene and the solution gines white fluorescence by irradiation of ultraviolet ray from a mercury lamp of 365 nm wavelength. In an XRD spectrum, it gives a diffraction peak assigned to CdS crystals of a Wurtzite type whereby it is confirmed to be CdS crystals.

### Synthetic Example 15

Synthesis of CdS Crystal Particles of a Core-Shell Type Having ZnS Shell

In an inner area of the glove box used in Synthetic Example 14, yellow solid powder (60.0 mg) of CdS crystal particles prepared in Synthetic Example 14 was mixed with trioctylphosphine (hereinafter, abbreviated as TOP; 0.62 g) in a glass bottle and sealed with Septum by the same manner as described in Synthetic Example 14 (hereinafter, the resulting mixed liquid will be referred to as “starting liquid B”). On the other hand, in the above-mentioned glove box, a 1M solution of diethyl zinc in n-hexane (0.75 mL), bis(trimethylsilyl) sulfide (0.1574 mL) and TOP (5 mL) were mixed in a glass bottle to prepare a solution and sealed with Septum by the same manner as above (hereinafter, the resulting mixed liquid will be referred to as “material solution C”). Apart from the above, as a reaction system, TOPO (6.2 g) was placed in a three-necked flask made of brown glass having an inner volume of 50 mL and dried in vacuo at 140° C. for 110 minutes. Then the inner temperature of the said reaction system was made 100° C., a substitution operation of the inner atmosphere with dry argon as same as that described in Synthetic Example 14 was carried out once, about 0.5 mL of n-hexane was added to the above-mentioned material liquid B, the resulting solution was added to the reaction system using an injector and a washing which was obtained upon washing the inner wall of the glass bottle where the material liquid B was placed with n-hexane (2 mL) was added to the reaction system similarly. After that, the reaction system was made vacuum for about 90 minutes whereupon n-hexane was evaporated. After that, the inner temperature of the reaction system was made 210° C., the above-mentioned substitution operation of the inner atmosphere with dry argon gas was carried out for three times, the above-mentioned material solution C was dropped thereinto during 29 minutes, the temperature of the reaction system was set at 90° C., the inner temperature of the reaction system was made 90° C. during about 40 minutes, the heat source was removed and the reaction system was allowed to stand at room temperature in an argon gas atmosphere for one night. On the next day, the reaction system was heated at 90° C. for 4 hours and allowed to cool down to 60° C. and, at that time, anhydrous n-butanol (3.3 mL) was added followed by cooling down to room temperature. The reaction solution was injected into anhydrous methanol (35 mL) at room temperature in the same manner as in Synthetic Example 13 followed by stirring for 5 minutes. When this was subjected to a centrifugal separation (4,000 rpm), there were obtained a supernatant liquid and a yellow precipitate and the said precipitate was collected by means of decantation and dissolved in pure toluene (2 mL). The toluene solution was injected into anhydrous methanol (20 mL) at room temperature, stirred for 5 minutes and centrifuged (4,000 rpm) to give a supernatant liquid and a yellow solid precipitate. The solid precipitate was collected by means of decantation, dissolved in pure toluene (2 mL), injected into a mixed liquid (20 mL) of anhydrous methanol/anhydrous n-butanol (in a ratio of 1/1 by volume) at room temperature, stirred for 5 minutes and centrifuged (3,000 rpm) and a supernatant liquid was removed by means of decantation to give a yellow solid precipitate. The solid was dried at room temperature in a dry nitrogen stream and dried in vacuo at room temperature for one night to give yellow solid powder (81.4 mg). The yellow solid powder prepared as such was soluble in chloroform and the resulting solution gave luminescence in an orange color by irradiation of ultraviolet ray from a mercury lamp of 365 nm wavelength. Hereinafter, the resulting semiconductor crystal particles will be abbreviated as CdS/ZnS-TOPO. The CdS crystal particles of Synthetic Example 14 gave white luminescence while, in the case of CdS/ZnS-TOPO, its emission band distribution was narrowed to an orange color region and, therefore, it was presumed that, since ZnS shell was formed on the surface of CdS core, luminescence in various wavelengths from surface level of the said core crystals disappeared.

### Synthetic Example 16

Synthesis of ZnSe Crystal Particles

A colorless and transparent three-necked flask made of Pyrex glass equipped with an air-cooling Liebig condenser and a thermocouple for adjusting the reaction temperature was covered with aluminum foil without aperture to shield from light. Hexadecylamine (Tokyo Kasei K. K.; 9 g) was placed in the said flask and subjected to deacrating dehydration by heating at 160° C. for 1 hour together with stirring by a magnetic stirrer, the inner area was made into a dry argon gas atmosphere and heating was conducted for 2 hours more with stirring. Then the temperature was set at 330° C. and the actual inner temperature measured became constant at 326° C. Apart therefrom, in a glove box used in the above Synthetic Example, a 1M solution of diethyl zinc in n-hexane (1.22 mL; 1.22 mmol), a solution of selenium (black powder of a single substance) in TOP (concentration: 0.780 mmol/g; the solution being 1.214 g; 0.946 mmol as selenium) and TOP (4 mL) were mixed in a glass bottle to prepare a solution and sealed with Septum by the same manner as in the above-mentioned Synthetic Example (hereinafter, the mixed liquid will be referred to as “starting solution F”). The starting solution F was subjected to a single continuous injection using an injector into the above flask in which the hexadecylamine was charged, the reaction temperature was re-set at 290° C. and that stage was defined as the starting time for the reaction. After 5 hours from the start of the reaction, TOPO (4 g) was added thereto, the heat source was removed and, when the mixture was cooled down to about 60° C., anhydrous n-butanol (3 mL) was added to dilute. The reaction solution was injected at room temperature to a mixed liquid (100 mL) of anhydrous methanol/anhydrous n-butanol (in a ratio of 2/3 by volume) which was a precipitating solvent whereupon a precipitate was formed and there was carried out an operation where the precipitate was centrifuged (4,000 rpm) and the supernatant liquid was removed by decantation. The resulting solid precipitate was dissolved in pure toluene (1 mL) and injected into the above precipitating solvent (50 mL) and the same isolating operation was carried out. The resulting solid precipitate was dissolved in pure toluene (2.5 mL) and injected into the above precipitating solvent (20 mL), the same isolating operation was repeated and the resulting solid was dried in vacuo at room temperature to give solid powder of ZnSe crystal particles (0.2172 g).

The solid powder prepared as such was soluble in chloroform and toluene. In its XRD spectrum, a diffraction peak assigned to ZnSe crystals is observed and, therefore, production of ZnSe crystal particles is confirmed. When a solution of the ZnSe crystal particles in pure toluene was irradiated with excitation light of 365 nm wavelength, it gave an exciton emission band where a peak wavelength was 412 nm whereby production of ZnSe crystal particles was confirmed as well. Incidentally, it was possible to control the peak wavelength of the said exciton emission band by controlling the above-mentioned reaction time.

### Synthetic Example 17

Synthesis of ZnSe Crystal Particles of Core-Shell Type Having ZnS Shell

In a glove box of a dry nitrogen atmosphere used in the above Synthetic Example, solid powder (40 mg) of the ZnSe crystal particles prepared in Synthetic Example 16 were mixed with TOP (0.4 mL) in a glass bottle and sealed by Septum as same as in the above Synthetic Example (hereinafter, the mixed liquid will be referred to as “material liquid G”). On the other hand, in the above glove box, a 1M solution of diethyl zinc in n-hexane (1.07 mL), bis(trimethylsilyl) sulfide (0.2257 mL) and TOP (3 mL) were mixed in a glass bottle to prepare a solution and sealed by Septum as same as above (hereinafter, the mixed liquid will be referred to as “material solution H”). Apart from the above, as a reaction system, TOPO (4 g) was placed in a three-necked flask made of Pyrex glass equipped with the light-shielded device as same as in Synthetic Example 16 and dried in vacuo at 180° C. for 1 hour, the inner temperature of the said reaction system was made 60° C. and there was formed a dry argon atmosphere. Then, about 0.5 mL of n-hexane was added to the above-mentioned material liquid G to prepare a solution, the solution was added to the reaction system using an injector and a washing prepared by washing the inner wall of the glass bottle in which the material liquid G was placed was similarly added to the reaction system. After that, the reaction system was vacuated for about 1 hour to evaporate n-hexane therefrom and made into a dry argon gas atmosphere and inner temperature of the reaction system was made 250° C. When dropping of the above-mentioned material solution H thereinto was finished during 13 minutes, the temperature was set at 200° C. and the actual temperature was made 200° C. within a few minutes. After 2 hours from the completion of dropping of material solution H, the temperature was set at 250° C. and, 4 hours and 6 hours thereafter, the temperature settings were changed to 280° C. and 300° C., respectively. After 7 hours, the heat source was removed to be allowed to cool down to room temperature and the reaction system was allowed to stand for one night in an argon gas atmosphere. On the next day, heating at 300° C. was further carried out for 1 hour. As a result of such reactions of raising the temperature, it was observed that the intensity of exciton luminescent band (peak wavelength: 416 nm) by excitation wavelength of 365 nm of a solution of sampled small amount of reaction solution in toluene significantly increased whereby it was presumed that ZnS shell was formed on the surface of the ZnSe crystal core, that contribution of the non-luminescent process via the surface level of the said core was suppressed and that emission intensity was enhanced. The reaction solution was recovered to nearly the room temperature and injected at room temperature into a mixed liquid of anhydrous methanol/anhydrous n-butanol (in a ratio of 2/3 by volume) (75 mL) which was a precipitating solvent, the resulting precipitate was centrifuged (4,000 rpm) and the supernatant liquid was removed by means of decantation to conduct an insolating operation. The solid precipitate prepared as such was dissolved in pure toluene (2.5 mL), injected into the above-mentioned precipitating solvent (40 mL) and subjected to the same isolating operation. The solid precipitate prepared as such was dissolved in pure toluene (1.7 mL), injected into anhydrous methanol (20 mL) and subjected to the same isolating operation and the resulting solid was dried in vacuo at room temperature to give solid powder (87.2 mg) of ZnSe crystal particles of a core-shell type having ZnS shell. An increase in weight as compared with the ZnSe crystal particles used as a material was presumably another proof for the formation of ZnS shell. As hereinafter, that will be abbreviated as ZnSe/ZnS-TOPO. The solid powder prepared as such was soluble in chloroform and toluene and a toluene solution gave an exciton luminescent band of 416 nm by excitation wavelength of 365 nm.

### Example 15

Synthesis of CdS Crystal Particles of a Core-Shell Type Having ZnS Shell Where HS-MTEG Is Bonded as an Organic Ligand

CdS crystal particles of a core-shell type having ZnS shell prepared in Synthetic Example 15 (CdS/ZnS-TOPO; 36.8 mg) and MTEG 11-mercaptoundecanoate prepared in Synthetic Example 13 (HS-METG; 173.5 mg) are placed in a colorless and transparent glass flask and, in a dry nitrogen atmosphere, heated to reflux for 30 minutes together with stirring in ethanol (Junsei Kagaku K. K.; 99.5% grade; 4 mL). Although CdS/ZnS-TOPO used as a material is substantially insoluble in ethanol, it is dissolved as the reaction proceeded and, therefore, it is presumed that TOPO is substituted with HS-MTEG. The residue obtained by concentrating the reaction solution in vacuo is stirred and washed with n-hexane (17 mL) and an operation of isolation of the solid is carried out by centrifugal separation (4,000 rpm) and then by decantation. The solid is dissolved in pure toluene (2 mL), injected into n-hexane (18 mL) to form a precipitate and an operation for the isolation of the solid as same as above is carried out. The same steps of dissolving in toluene, precipitating and isolating of the solid are carried out once again and the resulting solid powder is dried in vacuo at room temperature to give CdS crystal particles of a core-shell type having ZnS shell where HS-MTEG is bonded as an organic ligand. Hereinafter, the product will be referred to as CdS/ZnS-MTEG. In its solution in toluene, the CdS/ZnS-MTEG prepared as such gives luminescence in orange color by excitation wavelength of 365 nm as same as in the material CdS/ZnS-TOPO whereby it is noted that the core-shell type semiconductor crystal particles per se are not chemically changed substantially but the absorption and luminescence characteristics are retained. Content of the semiconductor crystals of the CdS crystal particles of a core-shell type prepared as such is usually about 60-70% by weight according to the above-mentioned TG measurement.

### Example 16

Synthesis of CdSe Crystal Particles of a Core-Shell Type Having ZnS Shell Where HS-MTEG Is Bonded as an Organic Ligand

The same operation as in Example 15 is carried out except that CdSe/ZnS-TOPO prepared in Synthetic Example 9 is used instead of CdS/ZnS-TOPO whereupon CdSe crystal particles of a core-shell type having ZnS shell where HS-MTEG is bonded as an organic ligand are prepared. The dissolving behavior thereof in ethanol is as same as that in Example 15. Hereinafter, the product will be referred to as CdSe/ZnS-MTEG. When CdSe/ZnS-MTEG prepared as such is subjected to an emission spectrum measurement under the same condition as mentioned in Synthetic Example 9, it gives substantially the same spectrum as that of CdSe/ZnS-TOPO and, therefore, it is noted that the semiconductor crystal particles of a core-shell type per se are not chemically changed substantially but the absorption and luminescence characteristics are retained. Content of the semiconductor crystals of the CdSe crystal particles of a core-shell type prepared as such is usually about 60-70% by weight according to the above-mentioned TG measurement.

### Example 17

Synthesis of ZnSe Crystal Particles of a Core-Shell Type Having ZnS Shell Where HS-MTEG Is Bonded as a Ligand

The same operation as in Example 15 is carried out except that ZnSe/ZnS-TOPO (60.2 mg) prepared in Synthetic Example 9 is used instead of CdS/ZnS-TOPO and that 150.4 mg of HS-MTEG is used. As compared with Example 15 or Example 16, progress of dissolving in ethanol is slow and, therefore, reaction time is made 5 hours (a homogeneous solution resulted after about 1 hour) to give ZnSe crystal particles of a core-shell type having ZnS shell where HS-MTEG is bonded as an organic ligand were prepared. Hereinafter, the product will be referred to as ZnSe/ZnS-MTEG. When ZnSe/ZnS-MTEG prepared as such is subjected to an emission spectrum measurement under the same condition as mentioned in Synthetic Example 17, it gives substantially the same spectrum as that of ZnSe/ZnS-TOPO and, therefore, it is noted that the semiconductor crystal particles of a core-shell type per se are not chemically changed substantially but the absorption and luminescence characteristics are retained. Content of the semiconductor crystals of the ZnSe crystal particles of a core-shell type prepared as such is usually about 75% by weight according to the above-mentioned TG measurement. When density of the whole semiconductor crystal moiety including the shell is presumed to be that (5.27) of ZnSe crystals of a sphalerite type while density of the residual organic components is presumed to be that (1.009) of HS-MTEG, content of the semiconductor crystals is calculated as 36% by volume.

### Example 18

Synthesis of CdSe Crystal Particles of a Core-Shell Type Where HS-MTEG Is Bonded as a Ligand

The same operation as in Example 15 is carried out except that CdSe crystal particles (53.1 mg) prepared in Synthetic Example 8 is used instead of CdS/ZnS-TOPO and that 100.6 mg of HS-MTEG is used. As compared with Example 15 or Example 16, progress of dissolving in ethanol is slow. Hereinafter, the resulting CdSe crystal particles where HS-MTEG is bonded as an organic ligand will be referred to as CdSe-MTEG. CdSe-MTEG prepared as such rarely showed luminescence by excitation wavelength of 365 nm but showed the same absorption spectrum shape as that of CdSe crystal particles prepared in Synthetic Example 8 and, therefore, it is presumed that the CdSe crystal structure is substantially retained. Content of the semiconductor crystals is 69% by weight according to the TG measurement for the CdSe crystal particles. When density of the semiconductor crystal moiety (CdSe) is presumed to be 5.66 while density of the residual organic components is presumed to be that (1.009) of HS-MTEG, content of the semiconductor crystals is calculated as 28% by volume.

### Example 19

Thin Film Containing CdS Crystal Particles of a Core-Shell Type (1)

A solution of CdS/ZnS-MTEG prepared in Example 15 in tetrahydrofuran (Junsei Kagaku K. K.) is applied on a clean quartz glass plate followed by drying, and it gives a transparent and hard film without stickiness. The film gives absorption and luminescence spectra of the same shapes as in the case of a solution of CdS/ZnS-MTEG and the absorbance of the absorption spectrum at the wavelength at the absorption edge of long wavelength side is less than 0.2 per 1 μm of the film thickness. Content of the semiconductor crystal particles in the film prepared as such is usually about 60-70% by weight according to the above-mentioned TG measurement.

### Example 20

Thin Film Containing CdS Crystal Particles of a Core-Shell Type (2)

The coating solution of Example 19 is mixed with polyethylene glycol of an average molecular weight of 500,000 (Wako Pure Chemical; 1 part by weight) to CdS/ZnS-MTEG (99 parts by weight) and the same coating operation is carried out to give a transparent and hard film without stickiness. The film gives absorption and luminescence spectra of the same shapes as in the case of a solution of CdS/ZnS-MTEG and the absorbance of the absorption spectrum at the wavelength at the absorption edge of long wavelength side is less than 0.2 per 1 μm of the film thickness. Content of the semiconductor crystal particles in the film prepared as such is usually about 60-70% by weight according to the above-mentioned TG measurement.

### Example 21

Thin Film Containing CdSe Crystal Particles of a Core-Shell Type

When the same coating operation as in Example 20 is carried out except that CdSe/ZnS-MTEG prepared in Example 16 is used instead of CdS/ZnS-MTEG, a transparent and hard film without stickiness is obtained. The film gives absorption and luminescence spectra of the same shapes as in the case of a solution of CdSe/ZnS-MTEG and the absorbance of the absorption spectrum at the wavelength at the absorption edge of long wavelength side is less than 0.2 per 1 μm of the film thickness. Content of the semiconductor crystal particles in the film prepared as such is usually about 70% by weight according to the TG measurement mentioned in Example 16.

### Example 22

Thin Film Containing CdSe Crystal Particles of a Core-Shell Type

When the same spin coating on a quartz glass plate as in Example 20 is carried out except that ZnSe/ZnS-MTEG prepared in Example 17 is used instead of CdS/ZnS-MTEG and the above-mentioned mixture of tetrahydrofuran with ethanol in a ratio by volume of 90/10 is used. As a result, a transparent and hard film without stickiness is obtained. The film gave absorption and luminescence spectra of the same shapes as in the case of a solution of CdSe/ZnS-MTEG and the absorbance of the absorption spectrum at the wavelength at the absorption edge of long wavelength side is less than 0.2 per 1 μm of the film thickness. Content of the semiconductor crystal particles in the film prepared as such is 74% by weight or 36% by weight from the result of Example 17. With regard to the refractive index of organic components contained in this film, when the value of triethylene glycol monomethyl ether (1.4380) is assumed and the refractive index of ZnSe crystals in a bulk state (2.8) is used, the refractive index of the resulting film as calculated from a proportional calculation by the % by volume is found to be 1.93.

### Example 23

Thin Film Containing CdSe Crystal Particles

CdSe-MTEG prepared in Example 18 is subjected to a press molding by means of pressure using an oil hydraulic pump used for the preparation of tablets for infrared absorption spectrum whereupon a transparent and hard thin film is obtained. The film gives absorption spectrum of the same shape as in the case of a solution of CdSe/ZnS-MTEG and the absorbance of the absorption spectrum at the wavelength at the absorption edge of long wavelength side is less than 0.2 per 1 μm of the film thickness. Content of the semiconductor crystal particles in the film is 69% by weight or 28% by weight from the result of Example 18. With regard to the refractive index of organic components contained in this thin film, when the value of triethylene glycol monomethyl ether (1.4380) is assumed and the refractive index of CdSe crystals in a bulk state (2.6) is used, the refractive index of the resulting film as calculated from a proportional calculation by the % by volume is found to be 1.76.

### Comparative Example 1

Solubility of Semiconductor Nanoparticles to Which TOPO Was Bonded (No. 1)

The semiconductor nanoparticles mainly comprising CdSe nanocrystals prepared in Synthetic Example 8 did not give a solution without turbidity even when heated to reflux in ethanol or in a 50% by weight aqueous solution of ethanol. From the above, it was noted that, since TOPO having a strong hydrophobicity was bonded as an organic ligand, its dispersity in alcohols and aqueous solvents was extremely bad.

### Comparative Example 2

Solubility of Semiconductor Nanoparticles to Which TOPO Was Bonded (No. 2)

The semiconductor nanoparticles mainly comprising the nanocrystals containing ZnS shell of Synthetic Example 9 did not give a solution without turbidity even when heated to reflux in ethanol or in a 50% by weight aqueous solution of ethanol. From the above, it was noted that, since TOPO having a strong hydrophobicity was bonded as an organic ligand, its dispersity in alcohols and aqueous solvents was extremely bad.

### Comparative Example 3

Solubility of Semiconductor Nanoparticles to Which No Organic Ligand Was Bonded

The residue obtained by a direct concentration in vacuo of an ethanolic solution containing ZnO nanocrystals obtained in Synthetic Example 10 gave ZnO powder which was unable to be re-dissolved in any of ethanol, water and a 50% by weight aqueous solution of ethanol. Thus, it was presumed that, unless some organic ligand is bonded onto the surface, nanoparticles of the semiconductor result in a secondary aggregation each other whereby no re-dissolving property is achieved.

### Comparative Example 4

Synthesis and Solubility of CdSe Nanoparticles to Which Hexadecylamine Was Coordinated (No. 1)

Toluene (5 mL) was added to CdSe-TOPO (0.0167 g) prepared by the operation mentioned in Synthetic Example 4 and hexadecylamine (hereinafter, abbreviated as HAD; Tokyo Kasei K. K.; 0.0655 g) and the mixture was heated with stirring in an argon atmosphere for about 2 hours at 90° C. The reaction solution was concentrated in vacuo to about 2 mL and added to methanol (20 mL) and the mixture was stirred for 5 minutes and then an insoluble substance was separated by means of centrifugal separation (3,000 rpm for 5 minutes) and decantation. The insoluble substance separated as such was dissolved in toluene (2 mL) again and injected into methanol (20 mL), the mixture was stirred for 5 minutes and separation was conducted as same as above by centrifugal separation (for 35 minutes) and decantation. The insoluble substance separated as such was dissolved in toluene (2 mL) again and injected into methanol (20 mL), the mixture was stirred for 5 minutes and the precipitate resulted by centrifugal separation (for 1 hour) was recovered. This was dried in vacuo at room temperature to remove the solvent whereupon a red solid (13.7 mg) was obtained.

The red solid prepared as such was tried to be dissolved in toluene and chloroform but, in any of the cases, it was not completely dissolved but there was something left undissolved. Its intensity of luminescence was about one half as compared with the original CdSe-TOPO.

Even when the red solid was heated to reflux in ethanol or in a 50% by weight aqueous solution of ethanol, a solution without turbidity was not obtained. From the above, it was noted that, since HDA having a strong hydrophobicity was bonded as an organic ligand, its dispersity in alcohols and aqueous solvents was extremely bad.

### Comparative Example 5

Synthesis and Solubility of CdSe Nanoparticles to Which Hexadecylamine Was Coordinated (No. 2)

CdSe-TOPO (0.0224 g) prepared according to an operation described in Synthetic Example 4 where the reaction time was made 11 minutes and HDA (2.0618 g) were heated with stirring at 200° C. for about 6 hours. After completion of the heating, methanol (20 mL) was added and the resulting insoluble substance was separated by means of centrifugal separation (3,000 rpm for 5 minutes) and decantation. The insoluble substance separated as such was dissolved in toluene (2 mL) again and injected into methanol (20 mL), the mixture was stirred for 5 minutes and separation was conducted as same as above by centrifugal separation and decantation. The solvent was removed by drying in vacuo at room temperature to give a red solid (24.1 mg).

The red solid prepared as such was soluble in toluene and chloroform. Intensity of luminescence when toluene was used as solvent was 4.1-fold as compared with the original CdSe-TOPO.

Even when the red solid was heated to reflux in ethanol or in a 50% by weight aqueous solution of ethanol, a solution without turbidity was not obtained. From the above, it was noted that, since HDA having a strong hydrophobicity was bonded as an organic ligand, its dispersity in alcohols and aqueous solvents was extremely bad.

It was found from Example 5, Comparative Example 4 and Comparative Example 5 that, in order to coordinate an alkylamine to nanocrystals, a large amount of alkylamine as compared with the original nanocrystals was necessary and that the reaction temperature was very high as well. It was found that, as compared with that, the ligand of the present invention was well coordinated in such an amount that was nearly the same weight of nanocrystals and the reaction temperature was low whereby it was suitable for production in an industrial scale.

### Comparative Example 6

Opaque Coated Film

CdS/ZnS-TOPO obtained in Synthetic Example 13 is dissolved in toluene and the solution is applied onto a quartz glass substrate and dried but there is only formed a coated film which is unable to be observed by naked eye and easily made into fine powder. Absorbance of the film in the wavelength of absorption edge at the side of long wavelength in the absorption spectrum is more than 0.2 per 1 μm of film thickness.

### Comparative Example 7

Opaque High-Molecular Matrix Coating Film (1)

CdS/ZnS-TOPO obtained in Synthetic Example 13 and PMMA (Tokyo Kasei K. K.; average degree of polymerization: 7,000-7,500) are dissolved in toluene in a ratio of 99/1 (by weight) and the solution is applied onto a quartz glass substrate and dried but there is only formed a coated film which is unable to be observed by naked eye and easily made into fine powder. Absorbance of the film in the wavelength of absorption edge at the side of long wavelength in the absorption spectrum is more than 0.2 per 1 μm of film thickness.

### Comparative Example 8

Opaque High-Molecular Matrix Coating Film (2)

The same operation as in Comparative Example 7 is carried out except that the ratio of CdS/ZnS-TOPO to PMMA is made 50/50 (by weight) and there is obtained a film which is turbid by an observation by naked eye using PMMA as a matrix. Absorbance of the film in the wavelength of absorption edge at the side of long wavelength in the absorption spectrum is more than 0.2 per 1 μm of film thickness.

Evaluation of Chemical Stability

When 10% hydrochloric acid was added under a room temperature condition to an ethanolic solution of the semiconductor nanoparticles obtained in Example 9 and Example 11, the former lost its luminescent ability within 30 seconds while the latter retained its luminescent ability. From the above, it was noted that, when a connected methylene group chain in the MTEG ester of ω-mercaptofatty acid was long, film of hydrophobic aliphatic chain was formed on the surface of semiconductor crystals and that there was achieved an effect of suppressing the chemical reaction on the surface of the said crystals by an approach of hydrophilic chemical species such as protonic acid.

Thus, the semiconductor nanoparticles of the present invention, where a poly(alkylene glycol) residue is attached onto the surface, have good solubility in solvents and dispersity in polymers, excellent coating property and controlled absorption and luminescence characteristics due to the quantum effect of the semiconductor crystals whereby they are applicable as various kinds of optical materials, biological analytical reagents, etc.

Although the present invention was illustrated in detail hereinabove by way of the specific embodiments, it is apparent for persons skilled in the art that various modifications and alterations thereof are possible without departing from the purpose and coverage of the present invention.

The disclosures of Japanese Patent Application No. 2000/360749, filed Nov. 28, 2000; Japanese Patent Application No. 2001/182747, filed Jun. 18, 2001; Japanese Patent Application No. 2001/259260, filed Aug. 29, 2001; and Japanese Patent Application No. 2002/018546, filed Jan. 28, 2002, are incorporated by reference herein in their entireties.

What is claimed is:

1. Semiconductor particles comprising
semiconductor crystals; and
at least one poly(alkylene glycol) residue attached to the semiconductor crystals.

2. The semiconductor particles according to claim 1, wherein the at least one poly(alkylene glycol) residue is attached to the semiconductor crystals via a group having a P═O structure, an amino group, or a mercapto group.

3. The semiconductor nanoparticles according to claim 1, wherein the at least one poly(alkylene glycol) residue is attached to the semiconductor crystals via an oxygen atom in a functional group represented by the following formula (1): 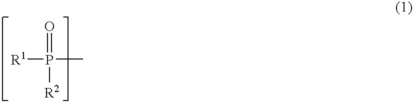
where R¹ and R² are the same or different and each is selected from the group consisting of a hydrogen atom, a hydroxyl group, an optionally-substituted alkyl group, an aryl group, an alkoxyl group, a trialkylsilyl group having 8 or less carbon atom(s), and a halogen atom.

4. The semiconductor nanoparticles according to claim 3, wherein at least one of R¹ and R² is a hydroxyl group.

5. The semiconductor nanoparticles according to claim 3, wherein the functional group represented by the formula (1) and the at least one poly(alkylene glycol) residue are linked via an alkylene group.

6. The semiconductor nanoparticles according to claim 5, wherein the alkylene group is an optionally-substituted alkylene group having 6-20 carbons.

7. The semiconductor nanoparticles according to claim 6, wherein the alkylene group is substituted with a substituent selected from the group consisting of a halogen atom, a nitro group, a hydroxyl group, a carboxyl group, an alkyl group having 8 or less carbon atoms, an alkoxyl group having 4 or less carbon atoms, and an aryl group having 4 or less carbon atoms.

8. The semiconductor nanoparticles according to claim 3, wherein the at least one poly(alkylene glycol) residue and the functional group represented by the formula (1) are each part of a compound represented by the following formula (10) that is attached to the semiconductor crystals: 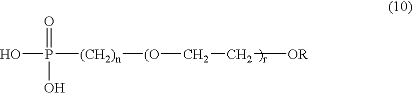
where R is a hydrogen atom or an alkyl group having 7 or less carbon atoms; n is a natural number of 20 or less; and r is 2-10.

9. The semiconductor nanoparticles according to claim 1, wherein the at least one poly(alkylene glycol) residue is attached to the semiconductor crystals via the amino group.

10. The semiconductor nanoparticles according to claim 9, wherein the at least one poly(alkylene glycol) residue is attached to the semiconductor crystals via an ω-aminofatty acid residue.

11. The semiconductor nanoparticles according to claim 1, wherein the at least one poly(alkylene glycol) residue is attached to the semiconductor crystals via the mercapto group.

12. The semiconductor nanoparticles according to claim 11, wherein the at least one poly(alkylene glycol) residue is attached to the semiconductor crystals via an ω-mercaptofatty acid residue.

13. The semiconductor nanoparticles according to claim 1, wherein the at least one poly(alkylene glycol) residue comprises a polyethylene glycol residue.

14. The semiconductor nanoparticles according to claim 13, wherein the at least one polyethylene glycol residue comprises a triethylene glycol monoalkyl ether residue.

15. The semiconductor nanoparticles according to claim 1, wherein the semiconductor crystals comprise a main constituent selected from the group consisting of a group II-group VI compound semiconductor composition, a group III-group V compound semiconductor composition, and a metal oxide composition.

16. The semiconductor nanoparticles according to claim 1, wherein the semiconductor crystals have a core-shell structure.

17. A method of making semiconductor nanoparticles, the method comprising
bonding at least one poly(alkylene glycol) residue to semiconductor crystals; and
producing the semiconductor nanoparticles of claim 1.

18. A method of using semiconductor nanoparticles, the method comprising
dispersing the semiconductor nanoparticles of claim 1 in a solvent to form a mixture; and
applying the mixture on a substrate to form a thin film.

19. The semiconductor nanoparticles according to claim 3, wherein the at least one poly(alkylene glycol) residue and the function group represented by the formula (1) are each part of a compound represented by the following formula (2): 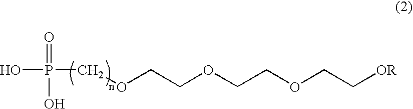
where R is a hydrogen atom or an alkyl group having 7 or less carbon atoms; and n is a natural number of 20 or less.

20. The semiconductor nanoparticles according to claim 2, wherein the at least one poly(alkylene glycol) residue is attached to the semiconductor crystals via a mercapto group of a ω-mercaptofatty acid represented by the following formula (9): 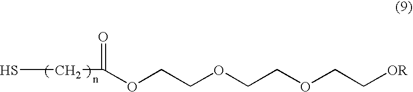
where R is a hydrogen atom or an alkyl group having 7 or less carbon atoms; and n is a natural number of 20 or less.
